(19) United States
(12) Patent Application Publication
(10) Pub. No.: US 2024/0215454 A1
(43) Pub. Date: Jun. 27, 2024

(54) APPARATUS

(71) Applicant: LG DISPLAY CO., LTD., Seoul (KR)

(72) Inventors: JungIm HWANG, Gyeonggi-do (KR); HyunJong NOH, Gyeonggi-do (KR); Junehwan KIM, Gyeonggi-do (KR)

(73) Assignee: LG DISPLAY CO., LTD., Seoul (KR)

(21) Appl. No.: 18/384,904

(22) Filed: Oct. 30, 2023

(30) Foreign Application Priority Data
Dec. 22, 2022 (KR) 10-2022-0181604

(51) Int. Cl. H10N 30/87; H04R 17/00; H10N 30/30

(52) U.S. Cl. CPC H10N 30/87; H04R 17/00; H10N 30/30

(57) ABSTRACT

An apparatus includes a vibration member, an active vibration device configured to vibrate the vibration member, and a passive vibration device disposed at a periphery of the active vibration device to generate electrical energy, based on a deformation of the passive vibration device.

### CROSS-REFERENCE TO RELATED APPLICATION

This application claims the priority of Korean Patent Application No. 10-2022-0181604 filed on Dec. 22, 2022, which is hereby incorporated by reference in its entirety.

### BACKGROUND

### Field of the Disclosure

The present disclosure relates to an apparatus.

### Description of the Background

Recently, the demands for slimming and thinning electronic devices are increasing. In speakers applied to electronic devices and the like, a piezoelectric device type capable of being implemented to have a thin thickness is attracting much attention instead of a voice coil type, based on the demand for slimming and thinning.

Speakers or vibration apparatuses, to which a piezoelectric device is applied, may be supplied with a driving power or a driving signal and may be driven or vibrate.

Furthermore, piezoelectric devices may be implemented with an energy harvester which self-generates energy with an electric charge which is generated based on a mechanical stress or deformation caused by an external force or vibration.

However, a piezoelectric device can be easily damaged by an external impact due to a fragile characteristic, and due to this, the reliability of the piezoelectric device is reduced and a sound characteristic and/or a sound pressure level characteristic are/is reduced.

### SUMMARY

Accordingly, the present disclosure is directed to an apparatus that substantially obviates one or more of problems due to limitations and disadvantages described above.

More specifically, the present disclosure is directed to providing an apparatus where reliability is improved and a sound characteristic and/or a sound pressure level characteristic are/is improved.

In addition, the present disclosure is directed to providing an apparatus which may generate electrical energy based on a vibration by sound reproduction.

Further, the present disclosure is directed to providing an apparatus where the reliability of sound reproduction is improved and which may generate electrical energy based on a vibration by sound reproduction.

Additional advantages, aspects, and features of the disclosure are set forth in part in the present disclosure and will also be apparent from the present disclosure or may be learned by practice of the inventive concepts provided herein. Other features, advantages, and aspects of the present disclosure may be realized and attained by the structure particularly pointed out in the present disclosure, or derivable therefrom, and claims hereof as well as the appended drawings.

To achieve these and other advantages and aspects of the present disclosure, as embodied and broadly described herein, in one or more aspects, an apparatus includes a vibration member, an active vibration device configured to vibrate the vibration member, and a passive vibration device at a periphery of the active vibration device to generate electrical energy, based on deformation of the passive vibration device.

According to one or more aspects of the present disclosure, the reliability of an apparatus may be improved by using a dielectric elastomer for replacing or complementing a piezoelectric material, and thus, a lifetime of the apparatus may increase.

According to one or more aspects of the present disclosure, by using a dielectric elastomer for replacing or complementing a piezoelectric material, an apparatus may be provided where the environment reliability of sound reproduction is improved and a sound characteristic and/or a sound pressure level characteristic are/is enhanced.

According to one or more aspects of the present disclosure, by using a dielectric elastomer for replacing or complementing a piezoelectric material, an apparatus may be provided where the environment reliability of sound reproduction is improved and electrical energy based on a vibration by sound reproduction may be generated.

An apparatus according to one or more aspects of the present disclosure may generate electrical energy based on a vibration by sound reproduction, and thus, production energy may be reduced, thereby contributing to decrease a greenhouse gas.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are exemplary and explanatory and are intended to provide further explanation of the disclosures as claimed.

### BRIEF DESCRIPTION OF THE DRAWINGS

The accompanying drawings, which are included to provide a further understanding of the disclosure and are incorporated in and constitute a part of this application, illustrate aspects of the disclosure and together with the description serve to explain principles of the disclosure.

FIG. 1 illustrates an apparatus according to an aspect of the present disclosure.

FIG. 2 is a cross-sectional view taken along line I-I′ illustrated in FIG. 1.

FIG. 3 illustrates for describing a non-vibration state of an apparatus according to an aspect of the present disclosure illustrated in FIG. 2.

FIG. 4 illustrates for describing a vibration state of the apparatus according to an aspect of the present disclosure illustrated in FIG. 2

FIG. 5 is another cross-sectional view taken along line I-I′ illustrated in FIG. 1 according to another aspect of the present disclosure.

FIG. 6 illustrates for describing a vibration state of an apparatus according to another aspect of the present disclosure illustrated in FIG. 5.

FIG. 7 is another cross-sectional view taken along line I-I′ illustrated in FIG. 1 according to another aspect of the present disclosure.

FIG. 8 illustrates for describing a vibration state of an apparatus according to another aspect of the present disclosure illustrated in FIG. 7.

FIG. 9 illustrates an arrangement structure of an active vibration device and a passive vibration device according to an aspect of the present disclosure.

FIG. 10 illustrates an arrangement structure of an active vibration device and a passive vibration device according to another aspect of the present disclosure.

FIG. 11 illustrates an arrangement structure of an active vibration device and a passive vibration device according to another aspect of the present disclosure.

FIG. 12 illustrates an arrangement structure of an active vibration device and a passive vibration device according to another aspect of the present disclosure.

FIG. 13 illustrates an active vibration device according to an aspect of the present disclosure.

FIG. 14 is a cross-sectional view taken along line II-II′ illustrated in FIG. 13 according to an aspect of the present disclosure.

FIG. 15 illustrates a passive vibration device according to an aspect of the present disclosure.

FIG. 16 is a cross-sectional view taken along line III-III′ illustrated in FIG. 15 according to an aspect of the present disclosure.

FIG. 17 illustrates a passive vibration part according to another aspect of the present disclosure.

FIG. 18 illustrates an active vibration device and a passive vibration device according to another aspect of the present disclosure.

FIG. 19 is a cross-sectional view taken along line IV-IV′ illustrated in FIG. 18 according to another aspect of the present disclosure.

FIG. 20 is a cross-sectional view taken along line V-V′ illustrated in FIG. 18 according to another aspect of the present disclosure.

FIG. 21 illustrates an active vibration device and a passive vibration device according to another aspect of the present disclosure.

FIG. 22 is a cross-sectional view taken along line VI-VI′ illustrated in FIG. 21 according to another aspect of the present disclosure.

### DETAILED DESCRIPTION

Reference is now made in detail to aspects of the present disclosure, examples of which may be illustrated in the accompanying drawings. In the following description, when a detailed description of well-known functions, structures or configurations may unnecessarily obscure aspects of the present disclosure, a detailed description of such known functions or configurations may have been omitted for brevity. Further, repetitive descriptions can be omitted for brevity. The progression of processing steps and/or operations described is a non-limiting example.

Throughout the drawings and the detailed description, unless otherwise described, the same drawing reference numerals should be understood to refer to the same elements, features, or structures. The sizes, lengths, and thicknesses of layers, regions and elements, and depiction of thereof may be exaggerated for clarity, illustration, and/or convenience.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof will be clarified through the aspects described with reference to the accompanying drawings. The present disclosure may, however, be embodied in different forms and should not be construed as limited to the aspects set forth herein. Rather, these aspects are examples and are provided so that this disclosure may be thorough and complete to assist those skilled in the art to understand the inventive concepts without limiting the protected scope of the present disclosure.

Shapes (e.g., sizes, lengths, widths, heights, thicknesses, locations, radii, diameters, and areas), dimensions, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

Where the term “comprise,” “have,” “include,” “contain,” “constitute,” “made of,” “formed of,” or the like with respect to one or more elements is used, one or more other elements may be added unless a term such as “only” or the like is used. The terms used in the present disclosure are merely used to describe particular aspects, and are not intended to limit the scope of the present disclosure. The terms of a singular form may include plural forms unless the context clearly indicates otherwise.

The word “exemplary” is used to mean serving as an example or illustration, unless otherwise specified. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e. g., a level, range, dimension, size, or the like) is construed to include an error or tolerance range even where no explicit description of such an error or tolerance range is provided. An error or tolerance range may be caused by various factors (e. g., process factors, internal or external impact, noise, or the like). In interpreting a numerical value, the value is interpreted as including an error range unless explicitly stated otherwise.

In describing a positional relationship when the positional relationship between two parts (e.g., layers, films, regions, components, sections, or the like) is described, for example, using “on,” upon,” “on top of,” “over,” “under,” “above,” “below,” “beneath,” “near,” “close to,” “adjacent to,” “beside,” “next to,” “at or on a side of, ” or the like, one or more other parts may be located between two parts unless a more limiting term, such as “immediate(ly),” “direct(ly),” or “close(ly),” is used. For example, when a structure is described as being positioned “on,” upon,” “on top of,” “over,” “under,” “above,” “below,” “beneath,” “near,” “close to,” “adjacent to,” “beside,” “next to,” “on a side of,” or the like another structure, this description should be construed as including a case in which the structures contact each other as well as a case in which one or more additional structures are disposed or interposed therebetween. Furthermore, the terms “front,” “rear,” “back,”“left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the terms “first,” “second,” or the like may be used herein to describe various elements (e.g., layers, films, regions, components, sections, or the like), these elements should not be limited by these terms, for example, to any particular order, sequence, precedence, or number of elements. These terms are used only to distinguish one element from another. For example, a first element could be termed a second element, and, similarly, a second element could be termed a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, or the like) is described as “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other. Such terms may mean a wider range of lines or directions within which the components of the present disclosure may operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and may be meant as directions having wider directivities within the range within which the components of the present disclosure can operate functionally.

The term “at least one” should be understood as including any and all combinations of one or more of the associated listed items. For example, each of the phrases of “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements, “and/or” a third element should be understood to encompass one of the first, second, and third elements, as well as any and all combinations of the first, second and third elements. By way of example, A, B and/or C encompass only A; only B; only C; any of A, B, and C (e.g., A, B, or C); or some combination of A, B, and C (e.g., A and B; A and C; or B and C); or all of A, B, and C. Furthermore, an expression “A/B” may be understood as A and/or B. For example, an expression “A/B” can refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as different from one another. In another example, an expression “different from one another” may be understood as different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

In the present disclosure, examples of an apparatus may include a narrow-sense display apparatus such as an organic light emitting display (OLED) module or a liquid crystal module (LCM) including a display panel and a driver for driving the display panel. Also, examples of the display apparatus may include a set device (or a set apparatus) or a set electronic apparatus such as a notebook computer, a TV, a computer monitor, an equipment apparatus including an automotive apparatus or another type apparatus for vehicles, or a mobile electronic device such as a smartphone or an electronic pad, which is a complete product (or a final product) including an LCM or an OLED module.

Therefore, in the present disclosure, examples of the display apparatus may include a narrow-sense display apparatus itself, such as an LCM or an OLED module, etc., and a set device which is a final consumer device or an application product including the LCM or the OLED module, etc.

Depending on the case, an LCM or an OLED module including a display panel and a driver may be referred to as a narrow-sense display apparatus, and an electronic device which is a final product including an LCM or an OLED module may be referred to as a set device. For example, the narrow-sense display apparatus may include a display panel, such as an LCD or an OLED, and a source printed circuit board (PCB) which is a controller for driving the display panel. The set device may further include a set PCB which is a set controller electrically connected to the source PCB to overall control the set device.

A display panel applied to an aspect of the present disclosure may use all types of display panels such as a liquid crystal display panel, an organic light emitting diode (OLED) display panel, a quantum dot (QD) display panel, and an electroluminescent display panel, etc. The display panel according to an aspect of the present disclosure is not limited to a specific display panel. As an example, a display panel may be capable of being bezel-bent in a lower back plate supporting structure and/or a flexible substrate for OLED display panels. As an example, the display panel may have a bezel not bent to the lower back plate and/or the flexible substrate, and/or may be a rigid or flexible display panel. Also, a shape or a size of a display panel applied to a display apparatus according to an aspect of the present disclosure is not limited.

For example, when the display panel is the organic light emitting display panel, the display panel may include a plurality of gate lines, a plurality of data lines, and a plurality of pixels respectively provided in a plurality of pixel areas defined by intersections of the gate lines and the data lines. Also, the display panel may include an array substrate including a TFT which is an element for selectively applying a voltage to each of the pixels, an organic light emitting device layer on the array substrate, and an encapsulation substrate disposed on the array substrate to cover the organic light emitting device layer. The encapsulation substrate may protect the TFT and the organic light emitting device layer from an external impact and may reduce or prevent water (or moisture) or oxygen from penetrating into the organic light emitting device layer. Alternatively, a layer provided on the array substrate may include an inorganic light emitting layer (for example, a nano-sized material layer, a quantum dot, or the like) or an organic light emitting layer.

Features of various aspects of the present disclosure may be partially or entirety coupled to or combined with each other, may be technically associated with each other, and may be variously operated, linked, or driven together in various ways. Aspects of the present disclosure may be implemented or carried out independently of each other, or may be implemented or carried out together in a co-dependent or related relationship. In one or more aspects, the components of each apparatus according to various aspects of the present disclosure may be operatively coupled and configured.

Unless otherwise defined, the terms (including technical and scientific terms) used herein have the same meaning as commonly understood by one of ordinary skill in the art to which example aspects belong. It should be further understood that terms, such as those defined in commonly used dictionaries, should be interpreted as having a meaning that is, for example, consistent with their meaning in the context of the relevant art and should not be interpreted in an idealized or overly formal sense, unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness. Thus, aspects of the present disclosure are not limited to a scale, dimension, size, or thickness illustrated in the drawings.

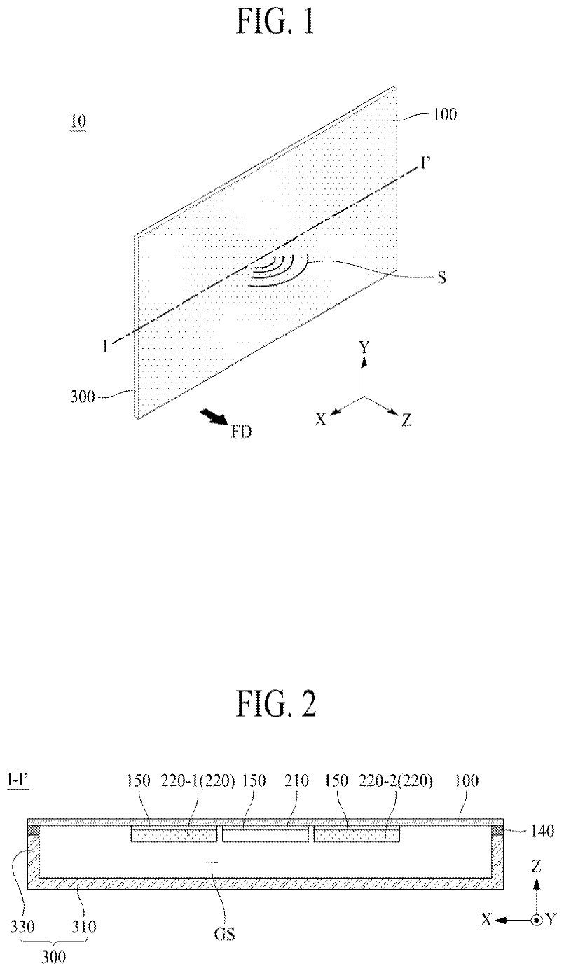

FIG. 1 illustrates an apparatus according to an aspect of the present disclosure. FIG. 2 is a cross-sectional view taken along line I-I′ illustrated in FIG. 1 according to an aspect of the present disclosure.

Referring to FIGS. 1 and 2, the apparatus 10 according to an aspect of the present disclosure may implement a sound apparatus, a sound output apparatus, a vibration apparatus, a vibration generating apparatus, a sound bar, a sound system, a sound apparatus for electronic devices, a sound apparatus for display, a sound apparatus for transport apparatuses, or a sound bar for transport apparatuses. For example, a transport apparatus may include one or more seats and one or more glass windows. For example, the transport apparatus may include a vehicle, a train, a ship, or an aircraft, but aspects of the present disclosure are not limited thereto. Also, the apparatus 10 according to an aspect of the present disclosure may be implement or realize an analog signage or a digital signage such as an advertising signboard, a poster, or a signboard.

The apparatus 10 according to an aspect of the present disclosure may be a display apparatus including a plurality of pixels, but aspects of the present disclosure are not limited thereto.

The display apparatus may include a display panel, including a plurality of pixels configuring a black/white or color image, and a driver for driving the display panel. Each of the plurality of pixels may be a subpixel configuring one of a plurality of colors configuring a color image. The apparatus 10 according to an aspect of the present disclosure may include a notebook computer, a television (TV), a computer monitor, an equipment apparatus including a specific form of a vehicle or a vehicular or automotive apparatus, and a set device (or a set apparatus) or a set electronic apparatus such as a smartphone or an electronic pad, which are complete products (or final products) including a display panel such as a liquid crystal display panel or an organic light emitting display panel.

The apparatus 10 according to an aspect of the present disclosure may include a vibration member 100, an active vibration device 210, and a passive vibration device 220.

The vibration member 100 may generate a vibration or may output a sound (or a sound wave), based on a displacement (or a vibration or driving) of the active vibration device 210. The vibration member 100 may transfer a vibration, generated by the active vibration device 210, to the passive vibration device 220. The vibration member 100 may be a vibration object, a display member, a display panel, a signage panel, a passive vibration member, a passive vibration plate, a front member, a rear member, a vibration panel, a sound panel, a passive vibration panel, a sound output plate, a sound vibration plate, or an image screen, but aspects of the present disclosure are not limited thereto. The vibration member 100 may comprise one or more of a display panel including a pixel configured to display an image, a screen panel on which an image is to be projected from a display apparatus, a lighting panel, a signage panel, a vehicular interior material, a vehicular glass window, a vehicular external material, a ceiling material of a building, an interior material of a building, a window of a building, an interior material of an aircraft, a window of an aircraft, metal, wood, rubber, plastic, glass, fiber, cloth, paper, leather, and mirror.

The vibration member 100 may be a display panel including a display portion (or a screen) including a plurality of pixels implementing a black/white or color image. For example, the display panel may use all types of display panels such as a liquid crystal display panel, an organic light emitting diode (OLED) display panel, a quantum dot (QD) display panel, and an electroluminescent display panel, but aspects of the present disclosure are not limited thereto. Accordingly, the vibration member 100 may generate one or more of a vibration and a sound, based on a displacement (or a vibration or driving) of the active vibration device 210. For example, the vibration member 100 may vibrate based on a displacement (or a vibration or driving) of the active vibration device 210 while displaying an image on the display portion, and thus, may generate or output a sound, synchronized with an image, to the display portion.

The vibration member 100 may be configured to be transparent, semitransparent, or opaque. The vibration member 100 may include a metal material having a material characteristic suitable for outputting a sound based on a vibration, or may include a nonmetal material (or a complex nonmetal material).

According to an aspect of the present disclosure, the metal material of the vibration member 100 may include one or more materials of stainless steel, aluminum (Al), an Al alloy, magnesium (Mg), an Mg alloy, and a magnesium-lithium (Mg—Li) alloy, but aspects of the present disclosure are not limited thereto. For example, the vibration member 100 may include a metal material of an Al material or may include a plastic material of a plastic or styrene material, but aspects of the present disclosure are not limited thereto. For example, the styrene material may be an ABS material. The ABS material may be acrylonitrile, butadiene, and styrene.

According to another aspect of the present disclosure, the nonmetal material (or the complex nonmetal material) of the vibration member 100 may include one or more materials (or substances) of plastic, fiber, leather, wood, cloth, rubber, carbon, glass, mirror, and paper, but aspects of the present disclosure are not limited thereto. For example, the paper may be cone paper for speakers. For example, the cone paper may be pulp or foam plastic, but aspects of the present disclosure are not limited thereto.

The vibration member 100 may have a planar structure. For example, the vibration member 100 may include a plate structure having a polygonal shape including a rectangular shape or a square shape. For example, the vibration member 100 may include a plate structure having a wholly uniform thickness, or may include a nonplanar structure, but aspects of the present disclosure are not limited thereto.

The vibration member 100 may include a horizontal length parallel to a first direction X and a vertical length parallel to a second direction Y intersecting with the first direction X. For example, with respect to the same plane, the first direction X may be a first horizontal direction or a first horizontal length direction of the vibration member 100, and the second direction Y may be a second horizontal direction intersecting with the first direction X or a second horizontal length direction of the vibration member 100. According to an aspect of the present disclosure, the vibration member 100 may include a rectangular shape where a horizontal length is relatively longer than a vertical length, or may include a square shape where a horizontal length is equal to a vertical length, but aspects of the present disclosure are not limited thereto.

The apparatus 10 according to an aspect of the present disclosure may include an active vibration device 210 and a passive vibration device 220.

The active vibration device 210 may be configured to vibrate the vibration member 100. The passive vibration device 220 may be at a periphery of the active vibration device 210 and may be deformed by a vibration of the active vibration device 210 to generate electrical energy. Each of the active vibration device 210 and the passive vibration device 220 may be disposed or provided in or at the vibration member 100.

The active vibration device 210 may be displaced (or vibrated or driven) based on a driving signal (or a vibration driving signal or a voice signal or a driving voltage) applied thereto to vibrate (or displace or drive) the vibration member 100. The active vibration device 210 may be connected or coupled to the vibration member 100 by an adhesive member 150. For example, the active vibration device 210 may be connected or coupled to a rear surface of the vibration member 100 by using the adhesive member 150. The active vibration device 210 may vibrate the vibration member 100 at the rear surface of the vibration member 100, and thus, may provide a user with a sound S and/or a haptic feedback, based on a vibration of the vibration member 100. The active vibration device 210 may output the sound S in a forward (or front) direction FD of the vibration member 100 by the vibration member 100 as a vibration plate. For example, the active vibration device 210 may be a vibration apparatus, a vibration structure, a vibration device, a vibrator, a vibration generating device, a vibration generating apparatus, a sound apparatus, a sound generating structure, a sound device, a sound generator, a sound generating apparatus, or a sound generator apparatus, but aspects of the present disclosure are not limited thereto.

The passive vibration device 220 may be deformed based on a force (or a vibration or pressure) applied thereto to generate electrical energy. The passive vibration device 220 may be connected or coupled to the vibration member 100 by the adhesive member 150. For example, the passive vibration device 220 may be connected or coupled to the rear surface of the vibration member 100 at a periphery of the active vibration device 210 by the adhesive member 150. The passive vibration device 220 may be disposed not to overlap with the active vibration device 210 on the vibration member 100. For example, the passive vibration device 220 may be spaced apart from the active vibration device 210 by a certain interval (or distance), at the rear surface of the vibration member 100. For example, the passive vibration device 220 may include a first passive vibration device 220-1 and a second passive vibration device 220-2. The first passive vibration device 220-1 and the second passive vibration device 220-2 may be disposed at peripheries of left and right sides (or left and right portions) of the active vibration device 210 with the active vibration device 210 therebetween. The passive vibration device 220 may be deformed by a force applied based on a vibration of the vibration member 100 generated by the active vibration device 210 at the rear surface of the vibration member 100, and thus, may generate electrical energy. For example, the passive vibration device 220 may be an energy generating apparatus, an energy generator apparatus, an energy generator, an energy converter, an energy generating device, an energy generator device, an energy conversion device, or an energy harvester, but aspects of the present disclosure are not limited thereto.

The active vibration device 210 and the passive vibration device 220 according to an aspect of the present disclosure may include an electroactive material or a piezoelectric material. For example, the active vibration device 210 may include an electroactive material or a piezoelectric material. Also, the passive vibration device 220 may include an electroactive material or a piezoelectric material. According to an aspect of the present disclosure, the active vibration device 210 and the passive vibration device 220 may include different materials. For example, the active vibration device 210 may include an electroactive material, and the passive vibration device 220 may include a piezoelectric material. Alternatively, the active vibration device 210 may include a piezoelectric material and the passive vibration device 220 may include an electroactive material, but aspects of the present disclosure are not limited thereto.

According to an aspect of the present disclosure, the active vibration device 210 may include an electroactive material. The electroactive material may include a dielectric elastomer. For example, the dielectric elastomer may include one or more of an acrylic-based polymer, a silicon-based polymer, and an epoxy-based polymer, but aspects of the present disclosure are not limited thereto. As another aspect of the present disclosure, the dielectric elastomer may include one or more of a liquid crystal elastomer, polyvinyl chloride (PVC), silicone, a PVC gel material, a polyvinylidene fluoride (PVDF) gel material, and urethane, but aspects of the present disclosure are not limited thereto.

When a voltage is applied to electrodes at both surfaces of the dielectric elastomer, the active vibration device 210, Maxwell stress P expressed as the following Equation 1 may be applied to the dielectric elastomer, based on a coulombic force.

$$P = {ε}_{r} {ε}_{0} {E}^{2} = {ε}_{r} {{ε}_{0} ( \frac{V}{z} )}^{2} \qquad [ Equation 1 ]$$

In Equation 1, P may denote a magnitude of Maxwell stress, εᵣ may denote a dielectric constant of the dielectric elastomer, ε₀ may denote a vacuum permittivity, E may denote a magnitude of an electric field, V may denote a level of an application voltage, and z may denote a thickness (or a distance between electrodes) of the dielectric elastomer. As the active vibration device 210 contracts in a thickness direction Z of the dielectric elastomer and expands in a horizontal direction X-Y, based on the Maxwell stress P, the active vibration device 210 may be autonomously displaced (or vibrated or driven) or may displace (or vibrate or drive) the vibration member, based on a displacement (or a vibration or driving) of the dielectric elastomer. For example, the active vibration device 210 may alternately repeat contraction and/or expansion, based on the Maxwell stress P of the dielectric elastomer, and thus, may be vibrated (or displaced or driven).

According to an aspect of the present disclosure, the passive vibration device 220 may include a piezoelectric material. When the passive vibration device 220 is deformed based on a physical vibration or force according to a piezoelectric effect (or a piezoelectric characteristic) of a piezoelectric material, a voltage may be generated, and thus, electrical energy may be generated. For example, electrical energy, which is generated as deformation by a vibration (or a displacement or driving) of the active vibration device 210 is alternately repeated based on the piezoelectric effect (or the piezoelectric characteristic), may be accumulated into the passive vibration device 210.

According to an aspect of the present disclosure, the active vibration device 210 may be better in availability than a piezoelectric material where a fragile characteristic is vulnerable, and thus, may include a dielectric elastomer which is good in restoring force corresponding to contraction and/or expansion based on a vibration, whereby the environment reliability of an apparatus and a sound characteristic and/or a sound pressure level characteristic may be improved. Also, the passive vibration device 220 may be disposed at a periphery of the active vibration device 210 and may convert a vibration of the active vibration device 210 into electrical energy, and thus, generated energy of an apparatus may be reduced.

Each of the active vibration device 210 and the passive vibration device 220 according to an aspect of the present disclosure may be connected or coupled to the rear surface of the vibration member 100 by an adhesive member 150.

The adhesive member 150 may include an adhesive layer (or a tacky layer) which is good in attaching force or adhesive force. For example, the adhesive member 150 may include an adhesive, a double-sided adhesive tape, a double-sided adhesive foam tape, a double-sided adhesive foam pad, or a tacky sheet, but aspects of the present disclosure are not limited thereto. For example, when the adhesive member 150 includes a tacky sheet (or a tacky layer), the adhesive member 150 may include only an adhesive layer or a tacky layer without a base member such as a plastic material.

The adhesive layer (or the tacky layer) of the adhesive member 150 according to an aspect of the present disclosure may include epoxy, acryl, silicone, or urethane, but aspects of the present disclosure are not limited thereto.

The adhesive layer (or the tacky layer) of the adhesive member 150 according to an aspect of the present disclosure may include a pressure sensitive adhesive (PSA), an optically cleared adhesive (OCA), or optically cleared resin (OCR), but aspects of the present disclosure are not limited thereto.

The apparatus 10 according to an aspect of the present disclosure may further include an enclosure 300 and a connection member 140.

The enclosure 300 may be disposed or provided at the rear surface of the vibration member 100. The enclosure 300 may be provided to support a rear edge portion (or a rear periphery portion) of the vibration member 100. The enclosure 300 may be provided to cover the rear surface of the vibration member 100. The enclosure 300 may include a gap space GS for accommodating the active vibration device 210 and the passive vibration device 220 and may have a box shape where one side (or one portion) is opened. For example, the enclosure 300 may include a box shape where one side (or one portion or an upper side or an upper portion) of the gap space GS is opened. For example, one opening of the enclosure 300 may be covered by the vibration member 100, and an air gap may be formed in a gap space GS between the enclosure 300 and the vibration member 100. For example, the enclosure 300 may be a housing, a case, an outer case, a case member, a housing member, a cabinet, a closed member, a closed cap, a closed box, or a sound box, but aspects of the present disclosure are not limited thereto. For example, the gap space GS of the enclosure 300 may be an internal space, an air gap, a vibration space, a sound space, a sounding box, or a closed space, but aspects of the present disclosure are not limited thereto.

The enclosure 300 according to an aspect of the present disclosure may include one or more materials of a metal material and a nonmetal material (or a complex nonmetal material), but aspects of the present disclosure are not limited thereto. For example, the enclosure 300 may include one or more materials of a metal material, plastic, and wood, but aspects of the present disclosure are not limited thereto. For example, the enclosure 300 may include a metal material of an Al material or may include a plastic material of a plastic or styrene material, but aspects of the present disclosure are not limited thereto. For example, the styrene material may be an ABS material. The ABS material may be acrylonitrile, butadiene, and styrene.

The enclosure 300 according to an aspect of the present disclosure may intactly (or consistently) maintain an impedance component based on air acting on the vibration member 100 when the vibration member 100 is vibrating. For example, air around the vibration member 100 may resist a vibration of the vibration member 100 and may act as an impedance component having a reactance component and another resistance, based on a frequency. Accordingly, the enclosure 300 may configure a closed space surrounding the vibration member 100, and thus, may intactly (or consistently) maintain an impedance component (or an air impedance or an elastic impedance) acting on the vibration member 100 by air, thereby enhancing a sound characteristic and/or a sound pressure level characteristic of a low-pitched sound band generated based on a vibration of the vibration member 100 and enhancing the quality of a sound of a high-pitched sound band.

The enclosure 300 according to an aspect of the present disclosure may include a bottom part 310 and a lateral part 330.

The bottom part 310 may be arranged in parallel with the vibration member 100. The bottom part 310 may be disposed to face the rear surface of the vibration member 100. The bottom part 310 may be disposed to cover the rear surface of the vibration member 100. The bottom part 310 may be spaced apart from the rear surface of the vibration member 100. For example, the bottom part 310 may be spaced apart from the rear surface of the vibration member 100 with a gap space GS (or an internal space) therebetween. For example, the bottom part 310 may be a plate, a bottom plate, a housing plate, or a housing bottom part, but aspects of the present disclosure are not limited thereto.

The lateral part 330 may be connected with an edge portion (or a periphery portion) of the bottom part 310. For example, the lateral prat 330 may include a structure which is bent from an edge portion (or a periphery portion) of the bottom part 310. For example, the lateral part 330 may be parallel to a third direction Z, or may be inclined with respect to the third direction Z. For example, the enclosure 300 may include two or more lateral parts 330. For example, the lateral part 330 may include first to fourth lateral parts. For example, the lateral part 330 may be a lateral surface, a sidewall, a supporting sidewall, a case lateral surface, a case sidewall, a housing lateral surface, or a housing sidewall, but aspects of the present disclosure are not limited thereto.

The lateral part 330 may be provided as one body with the bottom part 310. For example, the bottom part 310 and the lateral part 330 may be integrated as one body. Therefore, a gap space GS surrounded by the lateral part 330 may be provided on the bottom part 310. Accordingly, the bottom part 310 and the lateral part 330 may have a box shape where one side (or one portion) is opened.

The lateral part 330 may be connected or coupled to the rear surface of the vibration member 100 by a connection member 140. For example, the lateral part 330 may be connected or coupled to an edge portion (or a periphery portion) of the vibration member 100 by the connection member 140. For example, the lateral part 330 may be connected or coupled to an edge portion (or a periphery portion) of the rear surface of the vibration member 100 by the connection member 140.

According to an aspect of the present disclosure, the connection member 140 may be configured to minimize or prevent the transfer of a vibration of the vibration member 100 to the enclosure 300. The connection member 140 may include a material characteristic suitable for blocking a vibration. For example, the connection member 140 may include a material having elasticity. For example, the connection member 140 may include a material having elasticity, for vibration absorption (or impact absorption). The connection member 140 according to an aspect of the present disclosure may include polyurethane or polyolefin, but aspects of the present disclosure are not limited thereto. For example, the connection member 140 may include one or more of an adhesive, a double-sided tape, a double-sided foam tape, a double-sided foam pad, and a double-sided cushion tape, but aspects of the present disclosure are not limited thereto.

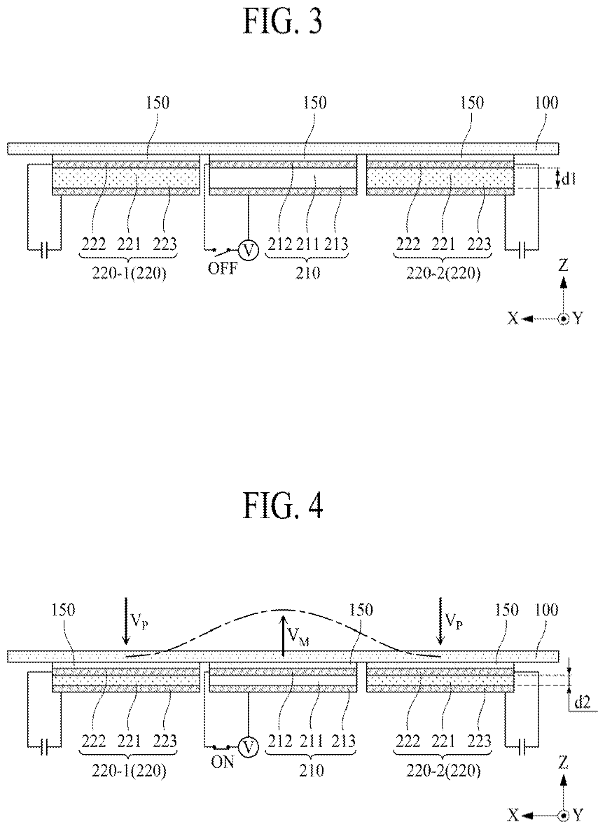

FIG. 3 illustrates for describing a non-vibration state of an apparatus according to an aspect of the present disclosure illustrated in FIG. 2. FIG. 4 illustrates for describing a vibration state of the apparatus according to an aspect of the present disclosure illustrated in FIG. 2.

Referring to FIGS. 3 and 4, the apparatus 10 according to an aspect of the present disclosure may include an active vibration device 210 and a passive vibration device 220.

The active vibration device 210 may be disposed or provided in or at the vibration member 100. For example, the active vibration device 210 may be disposed or provided at a center portion of the vibration member 100. The passive vibration device 220 may be disposed or provided in the vibration member 100. For example, the passive vibration device 220 may be disposed or provided at a periphery of the active vibration device 210 of the vibration member 100. The active vibration device 210 and the passive vibration device 220 may be disposed not to overlap with each other on the vibration member 100. The passive vibration device 220 may be disposed at a periphery of the active vibration device 210 with the active vibration device 210 therebetween. For example, the passive vibration device 220 may include a first passive vibration device 220-1 and a second passive vibration device 220-2. The first passive vibration device 220-1 and the second passive vibration device 220-2 may be disposed at a periphery of the active vibration device 210 with the active vibration device 210 therebetween. For example, the first passive vibration device 220-1 may be spaced apart from a left portion of the active vibration device 210, and the second passive vibration device 220-2 may be spaced apart from a right portion of the active vibration device 210.

Each of the active vibration device 210 and the passive vibration device 220 may include a first electrode layer 212 and 222 and a second electrode layer 213 and 223. For example, the first electrode layer 212 and 222 may be at a first surface (or an upper surface) of each of the active vibration device 210 and the passive vibration device 220. For example, the second electrode layer 213 and 223 may be at a second surface (or a rear surface) of each of the active vibration device 210 and the passive vibration device 220. For example, the active vibration device 210 may include the first electrode layer 212 and the second electrode layer 213. The first electrode layer 212 may be disposed at the first surface (or the upper surface) of the active vibration device 210. The second electrode layer 213 may be disposed at the second surface (or the rear surface) of the active vibration device 210. Also, the passive vibration device 220 may include the first electrode layer 222 and the second electrode layer 223. The first electrode layer 222 may be disposed at the first surface (or the upper surface) of the passive vibration device 220. The second electrode layer 223 may be disposed at the second surface (or the rear surface) of the passive vibration device 220. The first electrode layer 212 and the second electrode layer 213 of the active vibration device 210 may be electrically disconnected (or isolated) from the first electrode layer 222 and the second electrode layer 223 of the passive vibration device 220. For example, the first electrode layer 212 of the active vibration device 210 may be separated and electrically disconnected from the first electrode layer 222 of the passive vibration device 220. Also, the second electrode layer 213 of the active vibration device 210 may be separated and electrically disconnected from the second electrode layer 223 of the passive vibration device 220. The first electrode layer 222 of the passive vibration device 220 may be closer to the vibration member 100 than the second electrode layer 223. The second electrode layer 223 of the passive vibration device 220 may be configured to have stiffness different from stiffness of the first electrode layer 222, or configured to have stiffness being greater than or equal to stiffness of the first electrode layer 222.

The active vibration device 210 and the passive vibration device 220 may include a same material or different materials. The active vibration device 210 may include an active vibration part 211 between the first electrode layer 212 and the second electrode layer 213. Also, the passive vibration device 220 may include a passive vibration part 221 between the first electrode layer 222 and the second electrode layer 223. According to an aspect of the present disclosure, the active vibration part 211 of the active vibration device 210 and the passive vibration part 221 of the passive vibration device 220 may include different materials.

According to an aspect of the present disclosure, the active vibration part 211 of the active vibration device 210 may include a dielectric elastomer, and the passive vibration part 221 of the passive vibration device 220 may include a piezoelectric material.

When a voltage is not applied to the first electrode layer 212 and the second electrode layer 213, the active vibration part 211 may maintain a balance state (or an equilibrium state). Therefore, the passive vibration part 221 at a periphery of the active vibration part 211 may maintain a balance state. As illustrated in FIG. 3, in a state OFF where a voltage is not applied to the first electrode layer 212 and the second electrode layer 213 of the active vibration device 210, the active vibration part 211 and the passive vibration part 221 may maintain a balance state and may have a first thickness d1.

When a voltage is applied to the first electrode layer 212 and the second electrode layer 213 (the state ON in FIG. 4), the active vibration part 211 may be displaced (or contracted or expanded) in a thickness direction Z of the active vibration part 211, based on Maxwell stress applied to a dielectric elastomer included in the active vibration part 211. As illustrated in FIG. 4, when a voltage is applied to the first electrode layer 212 and the second electrode layer 213, a thickness of the active vibration part 211 may be displaced to a second thickness d2 which is less than the first thickness d1, based on a displacement (or contraction and/or expansion) of the dielectric elastomer included in the active vibration part 211. For example, as the on and off of a voltage applied to the first electrode layer 212 and the second electrode layer 213 are repeated, the active vibration part 211 may alternately repeat contraction and/or expansion of the active vibration part 211 to vibrate (or displace or drive).

A displacement (or contraction or expansion) of the active vibration part 211 may vibrate the vibration member 100. For example, the displacement (or contraction or expansion) of the active vibration part 211 may generate a force V_{M} (or vibration) applied to an upper portion of the vibration member 100 in the thickness direction Z. Therefore, the vibration member 100 may be displaced (or vibrated) by the force V_{M} (or vibration) applied to the upper portion of the vibration member 100. Also, in the vibration member 100, a force V_{P} (or vibration) applied to a lower portion of the vibration member 100 in the thickness direction Z may be transferred (or propagated) to a periphery of a displaced portion of the vibration member 100. The force V_{P} (or vibration) applied to the lower portion of the vibration member 100 may be applied to the passive vibration device 220 at a periphery of the active vibration device 210 and may deform the passive vibration device 220. For example, the force V_{P} (or vibration) applied to the lower portion of the vibration member 100 may be applied to each of the first passive vibration device 220-1 and the second passive vibration device 220-2. Also, the passive vibration part 221 of the first passive vibration device 220-1 and the passive vibration part 221 of the second passive vibration device 220-2 may be deformed by the force V_{P} (or vibration) applied to the lower portion of the vibration member 100. Accordingly, the passive vibration part 221 may generate a voltage, based on deformation of a piezoelectric material included in the passive vibration part 221, and may cause a potential difference between the first electrode layer 222 and the second electrode layer 223 of the passive vibration part 221, thereby generating electrical energy.

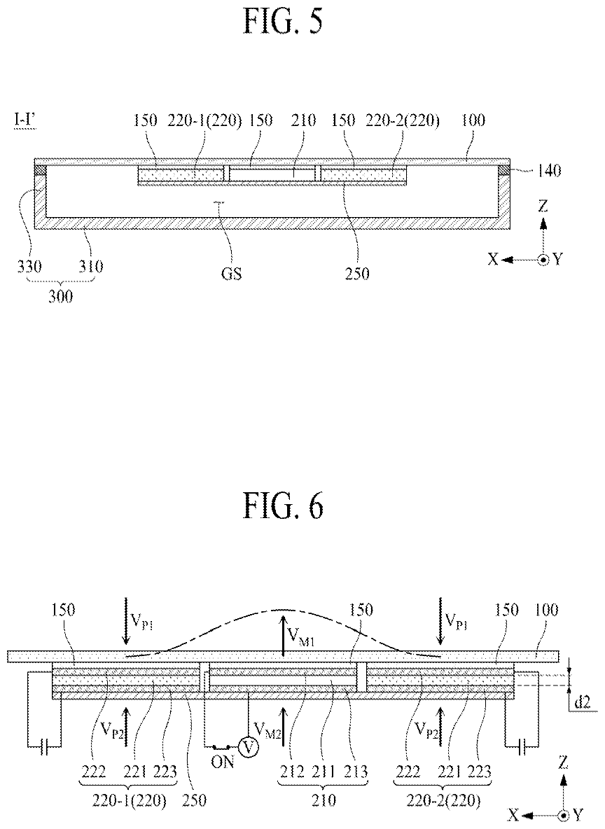

FIG. 5 is another cross-sectional view taken along line I-I′ illustrated in FIG. 1 according to another aspect of the present disclosure. FIG. 6 illustrates for describing a vibration state of an apparatus according to another aspect of the present disclosure illustrated in FIG. 5. FIGS. 5 and 6 illustrate an aspect where a supporting plate is added to the apparatus described above with reference to FIGS. 1 to 4. In the following description, therefore, like elements other than a supporting plate and relevant elements are referred to by like reference numerals, and repeated descriptions thereof are omitted or will be briefly given.

Referring to FIGS. 5 and 6, the apparatus 10 according to another aspect of the present disclosure may further include a supporting plate 250 which covers at least a portion of each of an active vibration device 210 and a passive vibration device 220.

The supporting plate 250 according to another aspect of the present disclosure may be disposed or connected or coupled to the active vibration device 210 and the passive vibration device 220 in common. The supporting plate 250 may be disposed or connected or coupled to a rear surface of each of the active vibration device 210 and the passive vibration device 220. For example, the supporting plate 250 may be disposed or connected or coupled to the rear surface of each of the active vibration device 210 and the passive vibration device 220 in common.

The supporting plate 250 may be disposed or connected or coupled to the rear surface of each of the active vibration device 210 and the passive vibration device 220 in common. The supporting plate 250 may be disposed or connected or coupled to the rear surface of each of the active vibration device 210 and the passive vibration device 220 in common by using an adhesive member. The supporting plate 250 may be configured to support the rear surface of each of the active vibration device 210 and the passive vibration device 220. The supporting plate 250 may be configured to transfer a vibration of the active vibration device 210 to the passive vibration device 220. For example, the supporting plate 250 may directly transfer a vibration of the active vibration device 210 to the passive vibration device 220.

The supporting plate 250 may include a metal material, or may include a nonmetal material (or a complex nonmetal material). The metal material of the supporting plate 250 may include one or more materials of stainless steel, Al, an Al alloy, Mg, a Mg alloy, and a Mg—Li alloy, but aspects of the present disclosure are not limited thereto. The nonmetal material (or the complex nonmetal material) of the supporting plate 250 may include one or more materials (or substances) of plastic, fiber, leather, wood, cloth, rubber, carbon, glass, and paper, but aspects of the present disclosure are not limited thereto. For example, the supporting plate 250 may be a second vibration plate, a rear vibration plate, a reinforcement plate, a stiff member, a stiff plate, a secondary member, or a secondary plate, but aspects of the present disclosure are not limited thereto.

Referring to FIG. 6, the supporting plate 250 may be disposed or connected or coupled to a rear surface of each of the second electrode layer 213 of the active vibration device 210 and the second electrode layer 223 of the passive vibration device 220. The supporting plate 250 may be connected or coupled to the rear surface of each of the second electrode layer 213 of the active vibration device 210 and the second electrode layer 223 of the passive vibration device 220 in common by an adhesive member. For example, the supporting plate 250 may include a metal material, and the adhesive member may have adhesive properties and may include an electrical insulating material. As another aspect of the present disclosure, the supporting plate 250 may include a metal material and may further include an insulation member which includes an electrical insulating material, to electrically insulate the second electrode layer 213 of the active vibration device 210 from the second electrode layer 223 of the passive vibration device 220. As another aspect of the present disclosure, the supporting plate 250 may include a nonmetal material (or a complex nonmetal material).

When a voltage is not applied to the first electrode layer 212 and the second electrode layer 213, the active vibration part 211 may maintain a balance state (or an equilibrium state). Therefore, the passive vibration part 221 at a periphery of the active vibration part 211 may maintain a balance state. As illustrated in FIG. 3, in a state where a voltage is not applied to the first electrode layer 212 and the second electrode layer 213 of the active vibration device 210, the active vibration part 211 and the passive vibration part 221 may maintain a balance state (or an equilibrium state) and may have a first thickness d1.

When a voltage is applied to the first electrode layer 212 and the second electrode layer 213, the active vibration part 211 may be displaced (or contracted or expanded) in a thickness direction Z of the active vibration part 211, based on Maxwell stress applied to a dielectric elastomer included in the active vibration part 211.

As illustrated in FIG. 6, when a voltage is applied to the first electrode layer 212 and the second electrode layer 213, a thickness of the active vibration part 211 may be displaced to a second thickness d2 which is less than a first thickness d1, based on a displacement (or contraction or expansion) of a dielectric elastomer included in the active vibration part 211. Also, the displacement (or contraction or expansion) of the active vibration part 211 may be directly transferred (or propagated) to the passive vibration part 221 through the supporting plate 250. For example, as the turn-on and turn-off of a voltage are repeated on the first electrode layer 212 and the second electrode layer 213, the active vibration part 211 may alternately repeat the contraction and/or expansion of the active vibration part 211 to vibrate (or displace or drive), and a vibration (or displacement or driving) of the active vibration part 211 may be directly transferred (or propagated) to the passive vibration part 221 through the supporting plate 250.

The vibration (or displacement or driving) of the active vibration part 211 may vibrate the vibration member 100. For example, the vibration (or displacement or driving) of the active vibration part 211 may generate a force V_{M1} (or vibration) which is applied upward in the thickness direction Z of the vibration member 100. Therefore, the vibration member 100 may be displaced (or vibrated) by the force V_{M1} (or vibration) which is applied upward with respect to the vibration member 100. Also, a force V_{P1} (or vibration) which is applied downward in the thickness direction Z of the vibration member 100 may be transferred (or propagated) to a periphery of a displaced portion of the vibration member 100. The force V_{P1} (or vibration) applied in a downward direction of the vibration member 100 may be applied to the passive vibration device 220 at a periphery of the active vibration device 210 to deform the passive vibration device 220. For example, the force V_{P1} (or vibration) applied in the downward direction of the vibration member 100 may be applied to each of the first passive vibration device 220-1 and the second passive vibration device 220-2. Also, the passive vibration part 221 of the first passive vibration device 220-1 and the passive vibration part 221 of the second passive vibration device 220-2 may be deformed by the force V_{P1} (or vibration) applied in the downward direction of the vibration member 100. Accordingly, the passive vibration part 221 may generate a voltage based on a deformation of a piezoelectric material included in the passive vibration part 221 and may cause a potential difference between the first electrode layer 222 and the second electrode layer 223 of the passive vibration part 221 to generate electrical energy.

A displacement (or contraction or expansion) of the active vibration part 211 may be directly transferred to the passive vibration part 221 through the supporting plate 250. For example, the displacement (or contraction or expansion) of the active vibration part 211 may be performed along with the supporting plate 250 connected with a rear surface of the active vibration part 211 and may generate a force V_{M2} applied in an upward direction of the supporting plate 250. Therefore, the supporting plate 250 may be moved by the force V_{M2} (or vibration) applied upward. Also, the force V_{M2} applied upward may be identically act on a periphery of a portion, connected with the active vibration device 210, of the supporting plate 250. The force V_{M2} (or vibration) applied in an upward direction of the supporting plate 250 may be applied to the passive vibration device 220 at a periphery of the active vibration device 210 and may deform the passive vibration device 220. For example, a force V_{P2} (or vibration) applied in an upward direction of the supporting plate 250 may be applied to the passive vibration device 220 at a periphery of the active vibration device 210 and may deform the passive vibration device 220. For example, the force V_{P2} (or vibration) applied in the upward direction of the supporting plate 250 may be applied to each of the first passive vibration device 220-1 and the second passive vibration device 220-2. Also, the passive vibration part 221 of the first passive vibration device 220-1 and the passive vibration part 221 of the second passive vibration device 220-2 may be deformed by the force V_{P2} (or vibration) applied in the upward direction of the supporting plate 250. Accordingly, the passive vibration part 221 may generate a voltage based on a deformation of a piezoelectric material included in the passive vibration part 221 and may cause a potential difference between the first electrode layer 222 and the second electrode layer 223 of the passive vibration part 221 to generate electrical energy.

According to another aspect of the present disclosure, a displacement (or contraction or expansion) of the active vibration device 210 may be transferred to an upper surface and a lower portion of the passive vibration device 220 through the vibration member 100 and the supporting plate 250, and thus, a deformation of the passive vibration device 220 may be relatively larger performed. Accordingly, the passive vibration part 221 may generate a relatively higher voltage, based on a relatively larger deformation of a piezoelectric material of the passive vibration part 221 and may enhance an output of generated electrical energy.

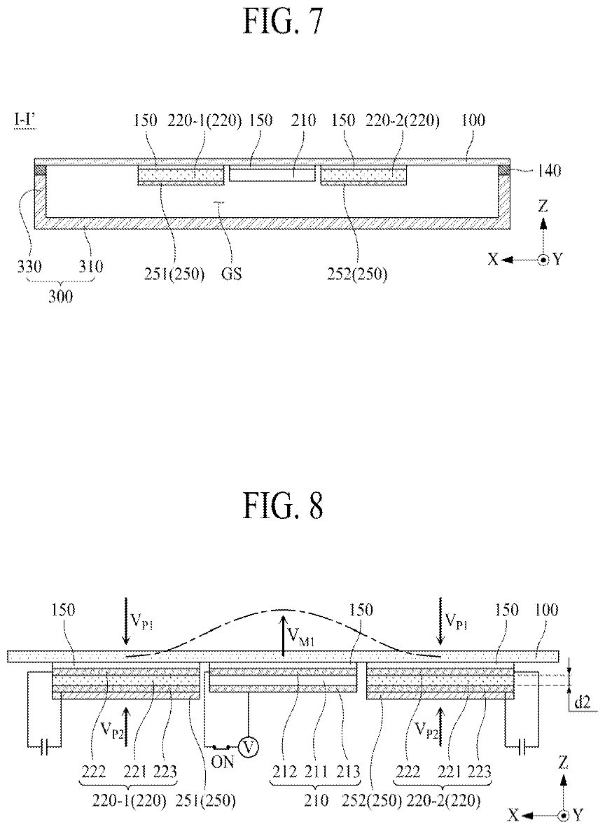

FIG. 7 is another cross-sectional view taken along line I-I′ illustrated in FIG. 1 according to another aspect of the present disclosure. FIG. 8 illustrates for describing a vibration state of an apparatus according to another aspect of the present disclosure illustrated in FIG. 7. FIGS. 7 and 8 illustrate an aspect implemented by modifying a configuration of a supporting plate in the apparatus described above with reference to FIGS. 1 to 6. In the following description, therefore, like elements other than a supporting plate and relevant elements are referred to by like reference numerals, and repeated descriptions thereof are omitted or will be briefly given.

Referring to FIGS. 7 and 8, the apparatus 10 according to another aspect of the present disclosure may further include a supporting plate 250 which covers at least a portion of each of an active vibration device 210 and a passive vibration device 220.

The supporting plate 250 according to another aspect of the present disclosure may be disposed or connected or coupled to the passive vibration device 220. The supporting plate 250 may be connected or coupled to the passive vibration device 220 and may not be connected with the active vibration device 210. The supporting plate 250 may include a first supporting plate 251 and a second supporting plate 252. For example, the first supporting plate 251 may be disposed or connected or coupled to a first passive vibration device 220-1. Also, the second supporting plate 252 may be disposed or connected or coupled to a second passive vibration device 220-2.

The supporting plate 250 may be configured to contact a rear surface of the passive vibration device 220. For example, the first supporting plate 251 may be configured to contact a rear surface of the first passive vibration device 220-1. Also, the second supporting plate 252 may be configured to contact a rear surface of the second passive vibration device 220-2.

The first supporting plate 251 may be connected or coupled to the rear surface of the first passive vibration device 220-1 by an adhesive member. The second supporting plate 252 may be connected or coupled to the rear surface of the second passive vibration device 220-2 by an adhesive member. The first supporting plate 251 and the second supporting plate 252 may be configured to respectively support the rear surface of the first passive vibration device 220-1 and the rear surface of the second passive vibration device 220-2. The first supporting plate 251 and the second supporting plate 252 may be respectively disposed at the rear surface of the first passive vibration device 220-1 and the rear surface of the second passive vibration device 220-2.

Each of the first passive vibration device 220-1 and the second passive vibration device 220-2 may include a metal material, or may include a nonmetal material (or a complex nonmetal material). The metal material of each of the first passive vibration device 220-1 and the second passive vibration device 220-2 may include one or more materials of stainless steel, Al, an Al alloy, Mg, a Mg alloy, and a Mg—Li alloy, but aspects of the present disclosure are not limited thereto. The nonmetal material (or the complex nonmetal material) of each of the first passive vibration device 220-1 and the second passive vibration device 220-2 may include one or more materials (or substances) of plastic, fiber, leather, wood, cloth, rubber, carbon, glass, and paper, but aspects of the present disclosure are not limited thereto. For example, each of the first passive vibration device 220-1 and the second passive vibration device 220-2 may be a second vibration plate, a rear vibration plate, a reinforcement plate, a stiff member, a stiff plate, an auxiliary member, or an auxiliary plate, but aspects of the present disclosure are not limited thereto.

Referring to FIG. 8, the supporting plate 250 may be disposed or connected or coupled to a rear surface of a second electrode layer 223 of the passive vibration device 220. The supporting plate 250 may be connected or coupled to the rear surface of the second electrode layer 223 of the passive vibration device 220 by an adhesive member. For example, the first supporting plate 251 may be connected or coupled to a rear surface of a second electrode layer 223 of the first passive vibration device 220-1 by an adhesive member. Also, the second supporting plate 252 may be connected or coupled to a rear surface of a second electrode layer 223 of the second passive vibration device 220-2 by an adhesive member.

According to an aspect of the present disclosure, the supporting plate 250 may include a conductive metal material and may replace the second electrode layer 223 of the passive vibration device 220. For example, the supporting plate 250 may include a conductive metal material having stiffness which is greater than that of the first electrode layer 222 and may replace the second electrode layer 223 of the passive vibration device 220. In this case, the second electrode layer 223 of the passive vibration device 220 may be omitted. For example, the passive vibration device 220 may include a passive vibration part 221, a first electrode layer 222 disposed at a first surface (or an upper surface) of the passive vibration part 221, and a conductive supporting plate 250 (or a second electrode layer) disposed at a second surface (or a rear surface) of the passive vibration part 221.

When a voltage is not applied to the first electrode layer 212 and the second electrode layer 213, the active vibration part 211 may maintain a balance state. Therefore, the passive vibration part 221 at a periphery of the active vibration part 211 may maintain a balance state. As illustrated in FIG. 3, in a state where a voltage is not applied to the first electrode layer 212 and the second electrode layer 213 of the active vibration device 210, the active vibration part 211 and the passive vibration part 221 may maintain a balance state and may have a first thickness d1.

When a voltage is applied to the first electrode layer 212 and the second electrode layer 213, the active vibration part 211 may be displaced (or contracted or expanded) in a thickness direction Z of the active vibration part 211, based on Maxwell stress applied to a dielectric elastomer included in the active vibration part 211.

As illustrated in FIG. 8, when a voltage is applied to the first electrode layer 212 and the second electrode layer 213, a thickness of the active vibration part 211 may be displaced to a second thickness d2 which is less than a first thickness d1, based on a displacement (or contraction or expansion) of a dielectric elastomer included in the active vibration part 211. For example, as the turn-on and turn-off of a voltage are repeated on the first electrode layer 212 and the second electrode layer 213, the active vibration part 211 may alternately repeat the contraction and/or expansion of the active vibration part 211 to vibrate (or displace or drive).

The vibration (or displacement or driving) of the active vibration part 211 may vibrate the vibration member 100. For example, the vibration (or displacement or driving) of the active vibration part 211 may generate a force V_{M1} (or vibration) which is applied upward in the thickness direction Z of the vibration member 100. Therefore, the vibration member 100 may be displaced (or vibrated) by the force V_{M1} (or vibration) which is applied in an upward direction of the vibration member 100. Also, a force V_{P1} (or vibration) which is applied downward in the thickness direction Z of the vibration member 100 may be transferred (or propagated) to a periphery of a displaced portion of the vibration member 100. The force V_{P1} (or vibration) applied in a downward direction of the vibration member 100 may be applied to the passive vibration device 220 at a periphery of the active vibration device 210 to deform the passive vibration device 220. For example, the force V_{P1} (or vibration) applied in the downward direction of the vibration member 100 may be applied to each of the first passive vibration device 220-1 and the second passive vibration device 220-2. Also, the passive vibration part 221 of the first passive vibration device 220-1 and the passive vibration part 221 of the second passive vibration device 220-2 may be deformed by the force V_{P1} (or vibration) applied in the downward direction of the vibration member 100. Accordingly, the passive vibration part 221 may generate a voltage based on a deformation of a piezoelectric material included in the passive vibration part 221 and may cause a potential difference between the first electrode layer 222 and the second electrode layer 223 of the passive vibration part 221 to generate electrical energy.

A rear surface of the passive vibration part 221 may be supported by the supporting plate 250. For example, when the passive vibration part 221 is deformed by the force V_{P1} (or vibration) transferred through the vibration member 100, a force V_{P2} (or vibration) applied upward may be generated based on a supporting force by the supporting plate 250 supported by or fixed to the rear surface of the passive vibration part 221. Therefore, when the passive vibration part 221 is deformed, the force V_{P2} (or vibration) applied in an upward direction of the supporting plate 250 may additionally act on the passive vibration device 220. The force V_{P2} (or vibration) applied in the upward direction of the supporting plate 250 may be applied to the passive vibration part 221 and may increase a deformation of the passive vibration device 220. For example, the force V_{P2} (or vibration) applied in an upward direction of the first supporting plate 251 may increase a deformation of the first passive vibration device 220-1. Also, the force V_{P2} (or vibration) applied in an upward direction of the second supporting plate 252 may increase a deformation of the second passive vibration device 220-2. Accordingly, the passive vibration part 221 may generate a voltage based on a deformation of a piezoelectric material included in the passive vibration part 221 and may cause a potential difference between the first electrode layer 222 and the second electrode layer 223 of the passive vibration part 221 to generate electrical energy.

According to another aspect of the present disclosure, a displacement (or contraction or expansion) of the active vibration device 210 may be transferred to an upper surface and a lower portion of the passive vibration device 220 through the vibration member 100 and the supporting plate 250, and thus, a deformation of the passive vibration device 220 may be relatively larger performed. Accordingly, the passive vibration part 221 may generate a relatively higher voltage, based on a relatively larger deformation of a piezoelectric material of the passive vibration part 221 and may enhance an output of generated electrical energy.

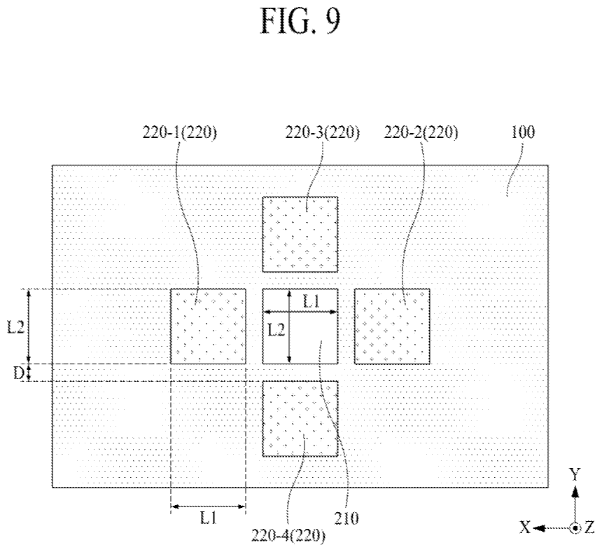

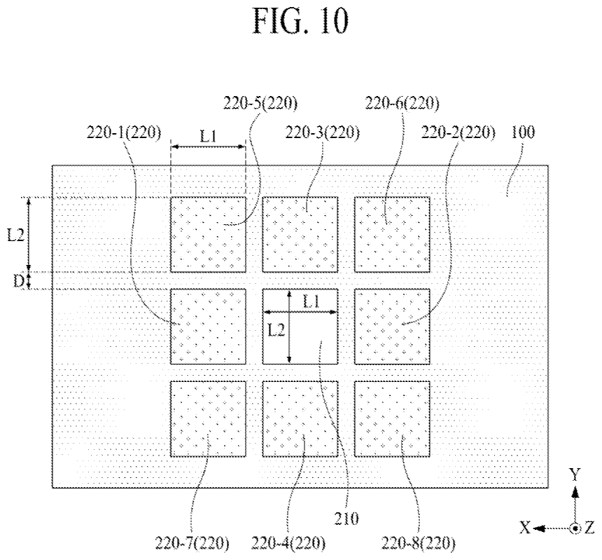

FIG. 9 illustrates an arrangement structure of an active vibration device and a passive vibration device according to an aspect of the present disclosure. FIGS. 10 to 12 illustrate another arrangement structure of an active vibration device and a passive vibration device according to another aspect of the present disclosure. FIGS. 9 to 12 one-dimensionally illustrate an arrangement structure of the active vibration device and the passive vibration device in the apparatus described above with reference to FIGS. 1 to 8. In the following description, therefore, like elements other than an arrangement structure of an active vibration device and a passive vibration device and relevant elements are referred to by like reference numerals, and repeated descriptions thereof are omitted or will be briefly given.

Referring to FIG. 9, an apparatus 10 according to an aspect of the present disclosure may include a vibration member 100, an active vibration device 210, and a plurality of passive vibration devices 220-1 to 220-4. For example, the apparatus 10 according to an aspect of the present disclosure may include one active vibration device 210 and may include the plurality of passive vibration devices 220-1 to 220-4.

The active vibration device 210 and the plurality of passive vibration devices 220-1 to 220-4 according to an aspect of the present disclosure may have the same size or different sizes. For example, each of the active vibration device 210 and the plurality of passive vibration devices 220-1 to 220-4 may have the same size. Each of the active vibration device 210 and the plurality of passive vibration devices 220-1 to 220-4 may include a tetragonal shape which has a first length L1 parallel to a first direction X and a second length L2 parallel to a second direction Y intersecting with the first direction X. For example, each of the active vibration device 210 and the plurality of passive vibration devices 220-1 to 220-4 may have a square shape where the first length L1 is equal to the second length L2, but aspects of the present disclosure are not limited thereto.

The active vibration device 210 may be disposed at a center portion of the vibration member 100. Each of the plurality of passive vibration devices 220-1 to 220-4 may be disposed at a peripheral portion of the active vibration device 210 of the vibration member 100. For example, each of the plurality of passive vibration devices 220-1 to 220-4 may be spaced apart from an edge (or a periphery) of the active vibration device 210 with a certain interval D. The active vibration device 210 and the plurality of passive vibration devices 220-1 to 220-4 may be spaced apart from one another with an equal interval D, but aspects of the present disclosure are not limited thereto.

The plurality of passive vibration devices 220-1 to 220-4 may include a first passive vibration device 220-1, a second passive vibration device 220-2, a third passive vibration device 220-3, and a fourth passive vibration device 220-4. The first passive vibration device 220-1 may be disposed at a periphery of a left side of the active vibration device 210. For example, the first passive vibration device 220-1 may be spaced apart from a left edge (or periphery) of the active vibration device 210 by a certain interval D. Also, the second passive vibration device 220-2 may be disposed at a periphery of a right side of the active vibration device 210. For example, the second passive vibration device 220-2 may be spaced apart from a right edge (or periphery) of the active vibration device 210 by a certain interval D. Also, the third passive vibration device 220-3 may be disposed at a periphery of an upper side of the active vibration device 210. For example, the third passive vibration device 220-3 may be spaced apart from an upper edge (or periphery) of the active vibration device 210 by a certain interval D. Also, the fourth passive vibration device 220-4 may be disposed at a periphery of a lower side of the active vibration device 210. For example, the fourth passive vibration device 220-4 may be spaced apart from a lower edge (or periphery) of the active vibration device 210 by a certain interval D.

For example, the first passive vibration device 220-1 and the second passive vibration device 220-2 may be disposed with the active vibration device 210 therebetween. For example, the first passive vibration device 220-1 and the second passive vibration device 220-2 may be arranged to be symmetrical with each other with respect to the active vibration device 210 therebetween. For example, the first passive vibration device 220-1 and the second passive vibration device 220-2 may be arranged to be horizontally (or left and right) symmetrical with each other with respect to the active vibration device 210 therebetween.

For example, the third passive vibration device 220-3 and the fourth passive vibration device 220-4 may be disposed with the active vibration device 210 therebetween. For example, the third passive vibration device 220-3 and the fourth passive vibration device 220-4 may be arranged to be symmetrical with each other with respect to the active vibration device 210 therebetween. For example, the third passive vibration device 220-3 and the fourth passive vibration device 220-4 may be arranged to be vertically (or up and down) symmetrical with each other with respect to the active vibration device 210 therebetween.

According to an aspect of the present disclosure, at least a portion of a periphery of the active vibration device 210 may be surrounded by the plurality of passive vibration devices 220-1 to 220-4. For example, a periphery of a left side, a periphery of a right side, a periphery of an upper side, and a periphery of a lower side of the active vibration device 210 may be surrounded by the first passive vibration device 220-1, the second passive vibration device 220-2, the third passive vibration device 220-3, and the fourth passive vibration device 220-4. For example, the plurality of passive vibration devices 220-1 to 220-4 surrounding the periphery of the left side, the periphery of the right side, the periphery of the upper side, and the periphery of the lower side of the active vibration device 210 may be deformed by a vibration (or displacement) generated by the active vibration device 210 to generate electrical energy. The plurality of passive vibration devices 220-1 to 220-4 may be disposed at positions to which a vibration is propagated in a left direction, a right direction, an up direction, and a down direction of the active vibration device 210, and thus, an output of generated electrical energy may be enhanced.

Referring to FIG. 10, an apparatus 10 according to another aspect of the present disclosure may include a vibration member 100, an active vibration device 210, and a plurality of passive vibration devices 220-1 to 220-8. For example, the apparatus 10 according to another aspect of the present disclosure may include one active vibration device 210 and may include the plurality of passive vibration devices 220-1 to 220-8.

The active vibration device 210 and the plurality of passive vibration devices 220-1 to 220-8 according to an aspect of the present disclosure may have the same size or different sizes. For example, each of the active vibration device 210 and the plurality of passive vibration devices 220-1 to 220-8 may have the same size. Each of the active vibration device 210 and the plurality of passive vibration devices 220-1 to 220-8 may include a tetragonal shape which has a first length L1 parallel to a first direction X and a second length L2 parallel to a second direction Y intersecting with the first direction X. For example, each of the active vibration device 210 and the plurality of passive vibration devices 220-1 to 220-8 may have a square shape where the first length L1 is equal to the second length L2, but aspects of the present disclosure are not limited thereto.

The active vibration device 210 may be disposed at a center portion of the vibration member 100. Each of the plurality of passive vibration devices 220-1 to 220-8 may be disposed at a peripheral portion of the active vibration device 210 of the vibration member 100. For example, each of the plurality of passive vibration devices 220-1 to 220-8 may be spaced apart from an edge (or a periphery) of the active vibration device 210 by a certain interval D. The active vibration device 210 and the plurality of passive vibration devices 220-1 to 220-8 may be spaced apart from one another with an equal interval D, but aspects of the present disclosure are not limited thereto.

The plurality of passive vibration devices 220-1 to 220-8 may include a first passive vibration device 220-1, a second passive vibration device 220-2, a third passive vibration device 220-3, a fourth passive vibration device 220-4, a fifth passive vibration device 220-5, a sixth passive vibration device 220-6, a seventh passive vibration device 220-7, and an eighth passive vibration device 220-8. The first passive vibration device 220-1 may be disposed at a periphery of a left side of the active vibration device 210. For example, the first passive vibration device 220-1 may be spaced apart from a left edge (or periphery) of the active vibration device 210 by a certain interval D. Also, the second passive vibration device 220-2 may be disposed at a periphery of a right side of the active vibration device 210. For example, the second passive vibration device 220-2 may be spaced apart from a right edge (or periphery) of the active vibration device 210 by a certain interval D. Also, the third passive vibration device 220-3 may be disposed at a periphery of an upper side of the active vibration device 210. For example, the third passive vibration device 220-3 may be spaced apart from an upper edge (or periphery) of the active vibration device 210 by a certain interval D. Also, the fourth passive vibration device 220-4 may be disposed at a periphery of a lower side of the active vibration device 210. For example, the fourth passive vibration device 220-4 may be spaced apart from a lower edge (or periphery) of the active vibration device 210 by a certain interval D. Also, the fifth passive vibration device 220-5 may be disposed at a periphery of a diagonal-direction between a left side and an upper side of the active vibration device 210. For example, the fifth passive vibration device 220-5 may be spaced apart from a corner between the left side and the upper side of the active vibration device 210 by a certain interval D. Also, the sixth passive vibration device 220-6 may be disposed at a periphery of a diagonal-direction between a right side and the upper side of the active vibration device 210. For example, the sixth passive vibration device 220-6 may be spaced apart from a corner between the right side and the upper side of the active vibration device 210 by a certain interval D. Also, the seventh passive vibration device 220-7 may be disposed at a periphery of a diagonal-direction between the left side and a lower side of the active vibration device 210. For example, the seventh passive vibration device 220-7 may be spaced apart from a corner between the left side and the lower side of the active vibration device 210 by a certain interval D. Also, the eighth passive vibration device 220-8 may be disposed at a periphery of a diagonal-direction between the right side and the lower side of the active vibration device 210. For example, the eighth passive vibration device 220-8 may be spaced apart from a corner between the right side and the lower side of the active vibration device 210 by a certain interval D.

For example, the first passive vibration device 220-1 and the second passive vibration device 220-2 may be disposed with the active vibration device 210 therebetween. For example, the first passive vibration device 220-1 and the second passive vibration device 220-2 may be arranged to be symmetrical with each other with respect to the active vibration device 210 therebetween. For example, the first passive vibration device 220-1 and the second passive vibration device 220-2 may be arranged to be horizontally (or a left and right) symmetrical with each other with respect to the active vibration device 210 therebetween.

For example, the third passive vibration device 220-3 and the fourth passive vibration device 220-4 may be disposed with the active vibration device 210 therebetween. For example, the third passive vibration device 220-3 and the fourth passive vibration device 220-4 may be arranged to be symmetrical with each other with respect to the active vibration device 210 therebetween. For example, the third passive vibration device 220-3 and the fourth passive vibration device 220-4 may be arranged to be vertically (or up and down) symmetrical with each other with respect to the active vibration device 210 therebetween.

For example, the first passive vibration device 220-1, the fifth passive vibration device 220-5, and the seventh passive vibration device 220-7 and the second passive vibration device 220-2, the sixth passive vibration device 220-6, and the eighth passive vibration device 220-8 may be disposed with the active vibration device 210, the third passive vibration device 220-3, and the fourth passive vibration device 220-4 therebetween. For example, the first passive vibration device 220-1, the fifth passive vibration device 220-5, and the seventh passive vibration device 220-7 and the second passive vibration device 220-2, the sixth passive vibration device 220-6, and the eighth passive vibration device 220-8 may be arranged to be symmetrical with one another with respect to the active vibration device 210, the third passive vibration device 220-3, and the fourth passive vibration device 220-4 therebetween. For example, the first passive vibration device 220-1, the fifth passive vibration device 220-5, and the seventh passive vibration device 220-7 and the second passive vibration device 220-2, the sixth passive vibration device 220-6, and the eighth passive vibration device 220-8 may be arranged to be horizontally (or left and right) symmetrical with one another with respect to the active vibration device 210, the third passive vibration device 220-3, and the fourth passive vibration device 220-4 therebetween.

For example, the third passive vibration device 220-3, the fifth passive vibration device 220-5, and the sixth passive vibration device 220-6 and the fourth passive vibration device 220-4, the seventh passive vibration device 220-7, and the eighth passive vibration device 220-8 may be disposed with the active vibration device 210, the first passive vibration device 220-1, and the second passive vibration device 220-2 therebetween. For example, the third passive vibration device 220-3, the fifth passive vibration device 220-5, and the sixth passive vibration device 220-6 and the fourth passive vibration device 220-4, the seventh passive vibration device 220-7, and the eighth passive vibration device 220-8 may be arranged to be symmetrical with one another with respect to the active vibration device 210, the first passive vibration device 220-1, and the second passive vibration device 220-2 therebetween. For example, the third passive vibration device 220-3, the fifth passive vibration device 220-5, and the sixth passive vibration device 220-6 and the fourth passive vibration device 220-4, the seventh passive vibration device 220-7, and the eighth passive vibration device 220-8 may be arranged to be vertically (or up and down) symmetrical with one another with respect to the active vibration device 210, the first passive vibration device 220-1, and the second passive vibration device 220-2 therebetween. According to another aspect of the present disclosure, the active vibration device 210 may be surrounded by the plurality of passive vibration devices 220-1 to 220-8. For example, a periphery of a left side, a periphery of a right side, a periphery of an upper side, a periphery of a lower side, a periphery of an upper left corner, a periphery of an upper right corner, a periphery of a lower left corner, and a periphery of a lower right corner of the active vibration device 210 may be surrounded by the first passive vibration device 220-1, the second passive vibration device 220-2, the third passive vibration device 220-3, the fourth passive vibration device 220-4, the fifth passive vibration device 220-5, the sixth passive vibration device 220-6, the seventh passive vibration device 220-7, and the eighth passive vibration device 220-8. For example, the plurality of passive vibration devices 220-1 to 220-8 surrounding the periphery of the left side, the periphery of the right side, the periphery of the upper side, the periphery of the lower side, the periphery of the upper left corner, the periphery of the upper right corner, the periphery of the lower left corner, and the periphery of the lower right corner of the active vibration device 210 may be deformed by a vibration (or displacement) generated by the active vibration device 210 to generate electrical energy. The plurality of passive vibration devices 220-1 to 220-8 may be disposed at positions to which a vibration is propagated in a left direction, a right direction, an up direction, a down direction, a diagonal direction between an upper side and a lower side, a diagonal direction between an upper side and a right side, a diagonal direction between a lower side and a left side, and a diagonal direction between the lower side and the right side of the active vibration device 210, and thus, an output of generated electrical energy may be enhanced.

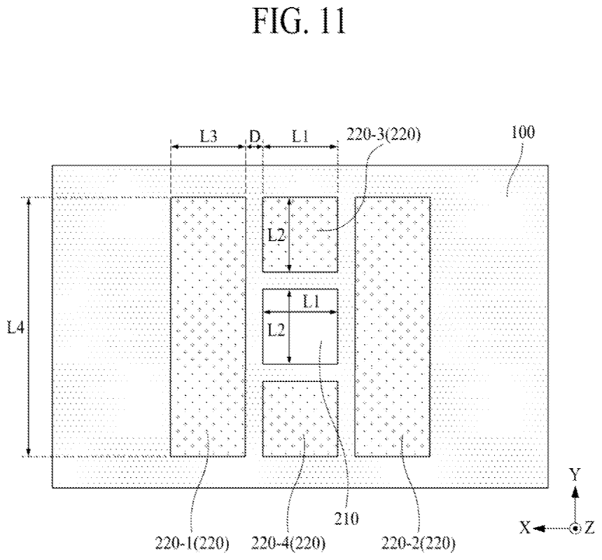

Referring to FIG. 11, an apparatus 10 according to another aspect of the present disclosure may include a vibration member 100, an active vibration device 210, and a plurality of passive vibration devices 220-1 to 220-4. For example, the apparatus 10 according to another aspect of the present disclosure may include one active vibration device 210 and may include the plurality of passive vibration devices 220-1 to 220-4.

The active vibration device 210 and the plurality of passive vibration devices 220-1 to 220-4 according to another aspect of the present disclosure may have the same size or different sizes. For example, the active vibration device 210 may have a size which differs from that of one or more of the plurality of passive vibration devices 220-1 to 220-4, or may have the same size as that of the other one or more of the plurality of passive vibration devices 220-1 to 220-4.

The active vibration device 210 may include a tetragonal shape which has a first length L1 parallel to a first direction X and a second length L2 parallel to a second direction Y intersecting with the first direction X. One or more of the plurality of passive vibration devices 220-1 to 220-4 may include a tetragonal shape which has the first length LI and the second length L2. Also, the other one or more of the plurality of passive vibration devices 220-1 to 220-4 may include a tetragonal shape which has a third length L3, which is equal to or different from the first length L1, and a fourth length L4 which is longer than the second length L2. For example, the active vibration device 210 may have a square shape where the first length L1 is equal to the second length L2, and some of the plurality of passive vibration devices 220-1 to 220-4 may have a square shape where the first length L1 is equal to the second length L2, or the other some of the plurality of passive vibration devices 220-1 to 220-4 may have a rectangular shape where the fourth length L4 is longer than the third length L3, but aspects of the present disclosure are not limited thereto.

The active vibration device 210 may be disposed at a center portion of the vibration member 100. Each of the plurality of passive vibration devices 220-1 to 220-4 may be disposed at a peripheral portion of the active vibration device 210 of the vibration member 100. For example, each of the plurality of passive vibration devices 220-1 to 220-4 may be spaced apart from an edge (or periphery) of the active vibration device 210 by a certain interval D. The active vibration device 210 and the plurality of passive vibration devices 220-1 to 220-4 may be spaced apart from one another at an equal interval D, but aspects of the present disclosure are not limited thereto.

The plurality of passive vibration devices 220-1 to 220-4 may include a first passive vibration device 220-1, a second passive vibration device 220-2, a third passive vibration device 220-3, and a fourth passive vibration device 220-4. The first passive vibration device 220-1 may be disposed at a periphery of a left side of the active vibration device 210. For example, the first passive vibration device 220-1 may have a rectangular shape which has the third length L3, which is equal to or different from the first length L1 of the active vibration device 210, and the fourth length L4 which is longer than the second length L2 of the active vibration device 210. For example, the first passive vibration device 220-1 may be spaced apart from a left edge of the active vibration device 210 by a certain interval D. For example, the first passive vibration device 220-1 may correspond to the active vibration device 210, the second passive vibration device 220-2, the third passive vibration device 220-3, and the fourth passive vibration device 220-4. Also, the first passive vibration device 220-1 may be disposed to extend to a periphery of a diagonal-direction between a left side and an upper side of the active vibration device 210 and may be disposed to extend to a periphery of a diagonal-direction between the left side and a lower side of the active vibration device 210. Also, the second passive vibration device 220-2 may be disposed at a periphery of a right side of the active vibration device 210. For example, the second passive vibration device 220-2 may have a rectangular shape which has the third length L3, which is equal to or different from the first length L1 of the active vibration device 210, and the fourth length L4 which is longer than the second length L2 of the active vibration device 210. For example, the second passive vibration device 220-2 may be spaced apart from a right edge (or periphery) of the active vibration device 210 by a certain interval D. For example, the second passive vibration device 220-2 may correspond to the active vibration device 210, the third passive vibration device 220-3, and the fourth passive vibration device 220-4. Also, the second passive vibration device 220-2 may be disposed to extend to a periphery of a diagonal-direction between a right side and an upper side of the active vibration device 210 and may be disposed to extend to a periphery of a diagonal-direction between the right side and a lower side of the active vibration device 210. Also, the third passive vibration device 220-3 may be disposed at a periphery of an upper side of the active vibration device 210. For example, the third passive vibration device 220-3 may have the same size and square shape as those of the active vibration device 210. For example, the third passive vibration device 220-3 may be spaced apart from an upper edge (or periphery) of the active vibration device 210 by a certain interval D. Also, the fourth passive vibration device 220-4 may be disposed at a periphery of a lower side of the active vibration device 210. For example, the fourth passive vibration device 220-4 may have the same size and square shape as those of the active vibration device 210. For example, the fourth passive vibration device 220-4 may be spaced apart from a lower edge (or periphery) of the active vibration device 210 by a certain interval D.

For example, the first passive vibration device 220-1 and the second passive vibration device 220-2 may be disposed with the active vibration device 210, the third passive vibration device 220-3, and the fourth passive vibration device 220-4 therebetween. For example, the first passive vibration device 220-1 and the second passive vibration device 220-2 may be arranged to be symmetrical with each other with respect to the active vibration device 210, the third passive vibration device 220-3, and the fourth passive vibration device 220-4 therebetween. For example, the first passive vibration device 220-1 and the second passive vibration device 220-2 may be arranged to be horizontally symmetrical with each other with respect to the active vibration device 210, the third passive vibration device 220-3, and the fourth passive vibration device 220-4 therebetween.

According to another aspect of the present disclosure, the active vibration device 210 may be surrounded by the first passive vibration device 220-1, the second passive vibration device 220-2, the third passive vibration device 220-3, and the fourth passive vibration device 220-4. For example, a periphery of a left side, a periphery of a right side, a periphery of an upper side, a periphery of a lower side, a periphery of an upper left corner, a periphery of an upper right corner, a periphery of a lower left corner, and a periphery of a lower right corner of the active vibration device 210 may be surrounded by the first passive vibration device 220-1, the second passive vibration device 220-2, the third passive vibration device 220-3, and the fourth passive vibration device 220-4. For example, the plurality of passive vibration devices 220-1 to 220-4 surrounding the periphery of the left side, the periphery of the right side, the periphery of the upper side, the periphery of the lower side, the periphery of the upper left corner, the periphery of the upper right corner, the periphery of the lower left corner, and the periphery of the lower right corner of the active vibration device 210 may be deformed by a vibration (or displacement) generated by the active vibration device 210 to generate electrical energy. The plurality of passive vibration devices 220-1 to 220-4 may be disposed at positions to which a vibration is propagated in a left direction, a right direction, an up direction, a down direction, a diagonal direction between an upper side and a lower side, a diagonal direction between an upper side and a right side, a diagonal direction between a lower side and a left side, and a diagonal direction between the lower side and the right side of the active vibration device 210, and thus, an output of generated electrical energy may be enhanced.

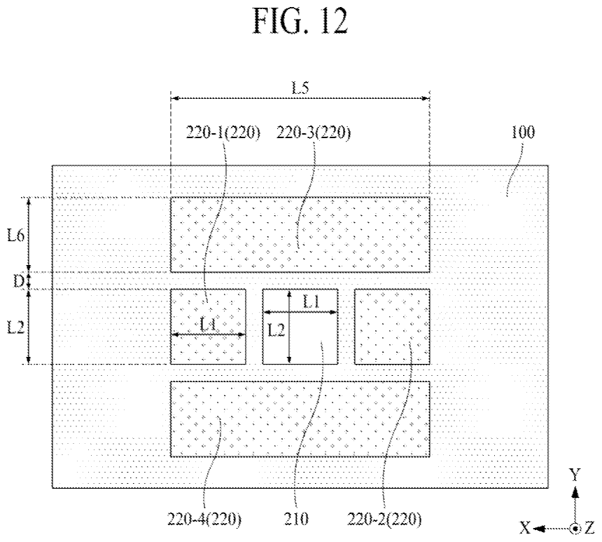

Referring to FIG. 12, an apparatus 10 according to another aspect of the present disclosure may include a vibration member 100, an active vibration device 210, and a plurality of passive vibration devices 220.

Referring to FIG. 12, the apparatus 10 according to another aspect of the present disclosure may include a vibration member 100, an active vibration device 210, and a plurality of passive vibration devices 220-1 to 220-4. For example, the apparatus 10 according to another aspect of the present disclosure may include one active vibration device 210 and may include the plurality of passive vibration devices 220-1 to 220-4. The active vibration device 210 and the plurality of passive vibration devices 220-1 to 220-4 according to another aspect of the present disclosure may have the same size or different sizes.

The active vibration device 210 may include a tetragonal shape which has a first length L1 parallel to a first direction X and a second length L2 parallel to a second direction Y intersecting with the first direction X. One or more of the plurality of passive vibration devices 220-1 to 220-4 may include a tetragonal shape which has the first length L1 and the second length L2. Also, the other one or more of the plurality of passive vibration devices 220-1 to 220-4 may include a rectangular shape which has a fifth length L5, which is longer than the first length L1, and a sixth length L6 which is equal to or different from the second length L2. For example, the active vibration device 210 may have a square shape where the first length L1 is equal to the second length L2, and some of the plurality of passive vibration devices 220-1 to 220-4 may have a square shape where the first length L1 is equal to the second length L2, or the other some of the plurality of passive vibration devices 220-1 to 220-4 may have a rectangular shape where the fifth length L5 is longer than the sixth length L6, but aspects of the present disclosure are not limited thereto.

The active vibration device 210 may be disposed at a center portion of the vibration member 100. Each of the plurality of passive vibration devices 220-1 to 220-4 may be disposed at a peripheral portion of the active vibration device 210 of the vibration member 100. For example, each of the plurality of passive vibration devices 220-1 to 220-4 may be spaced apart from an edge (or periphery) of the active vibration device 210 by a certain interval D. The active vibration device 210 and the plurality of passive vibration devices 220-1 to 220-4 may be spaced apart from one another at an equal interval D, but aspects of the present disclosure are not limited thereto.

The plurality of passive vibration devices 220-1 to 220-4 may include a first passive vibration device 220-1, a second passive vibration device 220-2, a third passive vibration device 220-3, and a fourth passive vibration device 220-4. The first passive vibration device 220-1 may be disposed at a periphery of a left side of the active vibration device 210. For example, the first passive vibration device 220-1 may have the same size and square shape as those of the active vibration device 210. For example, the first passive vibration device 220-1 may be spaced apart from a left edge (or periphery) of the active vibration device 210 by a certain interval D. Also, the second passive vibration device 220-2 may be disposed at a periphery of a right side of the active vibration device 210. For example, the second passive vibration device 220-2 may have the same size and square shape as those of the active vibration device 210. For example, the second passive vibration device 220-2 may be spaced apart from a right edge (or periphery) of the active vibration device 210 by a certain interval D. Also, the third passive vibration device 220-3 may be disposed at a periphery of an upper side of the active vibration device 210. For example, the third passive vibration device 220-3 may have a rectangular shape which has a fifth length L5, which is longer than the first length L1 of the active vibration device 210, and a sixth length L6 which is equal to or different from the second length L2 of the active vibration device 210. For example, the third passive vibration device 220-3 may be spaced apart from an upper edge (or periphery) of the active vibration device 210 by a certain interval D. For example, the third passive vibration device 220-1 may correspond to the active vibration device 210, the first passive vibration device 220-1, and the second passive vibration device 220-2. Also, the third passive vibration device 220-3 may be disposed to extend to a periphery of a diagonal-direction between an upper side and a left side of the active vibration device 210 and may be disposed to extend to a periphery of a diagonal-direction between the upper side and a right side of the active vibration device 210. Also, the fourth passive vibration device 220-4 may be disposed at a periphery of a lower side of the active vibration device 210. For example, the fourth passive vibration device 220-4 may have a rectangular shape which has the fifth length L5, which is longer than the first length LI of the active vibration device 210, and the sixth length L6 which is equal to or different from the second length L2 of the active vibration device 210. For example, the fourth passive vibration device 220-4 may be spaced apart from a lower edge (or periphery) of the active vibration device 210 by a certain interval D. For example, the fourth passive vibration device 220-4 may correspond to the active vibration device 210, the first passive vibration device 220-1, and the second passive vibration device 220-2. Also, the fourth passive vibration device 220-4 may be disposed to extend to a periphery of a diagonal-direction between the lower side and a left side of the active vibration device 210 and may be disposed to extend to a periphery of a diagonal-direction between the lower side and the right side of the active vibration device 210.

For example, the third passive vibration device 220-3 and the fourth passive vibration device 220-4 may be disposed with the active vibration device 210, the first passive vibration device 220-1, and the second passive vibration device 220-2 therebetween. For example, the third passive vibration device 220-3 and the fourth passive vibration device 220-4 may be arranged to be symmetrical with each other with respect to the active vibration device 210, the first passive vibration device 220-1, and the second passive vibration device 220-2 therebetween. For example, the third passive vibration device 220-3 and the fourth passive vibration device 220-4 may be arranged to be vertically symmetrical with each other with respect to the active vibration device 210, the first passive vibration device 220-1, and the second passive vibration device 220-2 therebetween.

According to another aspect of the present disclosure, the active vibration device 210 may be surrounded by the first passive vibration device 220-1, the second passive vibration device 220-2, the third passive vibration device 220-3, and the fourth passive vibration device 220-4. For example, a periphery of a left side, a periphery of a right side, a periphery of an upper side, a periphery of a lower side, a periphery of an upper left corner, a periphery of an upper right corner, a periphery of a lower left corner, and a periphery of a lower right corner of the active vibration device 210 may be surrounded by the first passive vibration device 220-1, the second passive vibration device 220-2, the third passive vibration device 220-3, and the fourth passive vibration device 220-4. For example, the plurality of passive vibration devices 220-1 to 220-4 surrounding the periphery of the left side, the periphery of the right side, the periphery of the upper side, the periphery of the lower side, the periphery of the upper left corner, the periphery of the upper right corner, the periphery of the lower left corner, and the periphery of the lower right corner of the active vibration device 210 may be deformed by a vibration (or displacement) generated by the active vibration device 210 to generate electrical energy. The plurality of passive vibration devices 220-1 to 220-4 may be disposed at positions to which a vibration is propagated in a left direction, a right direction, an up direction, a down direction, a diagonal direction between an upper side and a lower side, a diagonal direction between an upper side and a right side, a diagonal direction between a lower side and a left side, and a diagonal direction between the lower side and the right side of the active vibration device 210, and thus, an output of generated electrical energy may be enhanced.

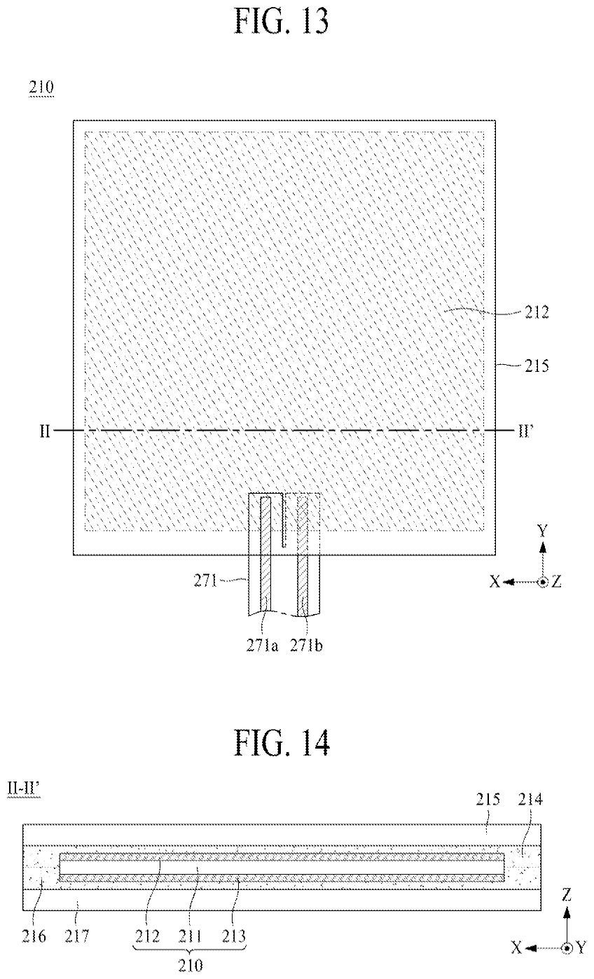

FIG. 13 illustrates an active vibration device according to an aspect of the present disclosure. FIG. 14 is a cross-sectional view taken along line II-II′ illustrated in FIG. 13 according to an aspect of the present disclosure.

Referring to FIGS. 13 and 14, the active vibration device 210 according to an aspect of the present disclosure may be a vibration apparatus, a vibration structure material, a vibration device, a vibrator, a vibration generating device, a vibration generating apparatus, a flexible vibration apparatus, a flexible vibration structure material, a flexible vibration device, a flexible vibrator, a flexible vibration generating device, a flexible vibration generating apparatus, a sound apparatus, a sound structure material, a sound device, a sound generator, a sound generating device, a sound generating apparatus, a flexible sound apparatus, a flexible sound structure material, a flexible sound device, a flexible sound generator, a flexible sound generating device, a flexible sound generating apparatus, a flexible actuator, a flexible speaker, a film speaker, a film actuator, or a film-type dielectric elastomer speaker, but aspects of the present disclosure are not limited thereto.

The active vibration device 210 may include a tetragonal shape which has a first length parallel to a first direction X and a second length parallel to a second direction Y. For example, the active vibration device 210 may have a square shape where the first length is equal to the second length, or may have a rectangular shape where one of the first length and the second length is relatively long, but aspects of the present disclosure are not limited thereto.

The active vibration device 210 according to an aspect of the present disclosure may include an active vibration part 211, a first electrode layer 212, and a second electrode layer 213.

The active vibration part 211 may include an electroactive material or a piezoelectric material having a piezoelectric effect. According to an aspect of the present disclosure, the active vibration part 211 may include an electroactive material. For example, the electroactive material may have a characteristic where a coulombic force acts based on a voltage applied to electrodes disposed at both surfaces, and simultaneously, a vibration is generated as Maxwell Stress is applied. The active vibration part 211 may include a transparent, semitransparent, or opaque piezoelectric material, and thus, the active vibration part 211 may be transparent, semitransparent, or opaque.

The active vibration part 211 may include an electroactive material. The electroactive material may include a dielectric elastomer. For example, the dielectric elastomer may include one or more of an acrylic polymer, a silicon-based polymer, and an epoxy-based polymer, but aspects of the present disclosure are not limited thereto. As another aspect of the present disclosure, the dielectric elastomer may include one or more of a liquid crystal elastomer, polyvinyl chloride (PVC), silicone, a PVC gel material, a polyvinylidene fluoride (PVDF) gel material, and urethane, but aspects of the present disclosure are not limited thereto.

The first electrode layer 212 may be disposed at a first surface (or an upper surface) of the active vibration part 211. For example, the first electrode layer 212 may have a common electrode form which is disposed at the whole first surface of the active vibration part 211. For example, the first electrode layer 212 may have substantially the same a shape as that of the active vibration part 211, but aspects of the present disclosure are not limited thereto.

The first electrode layer 212 according to an aspect of the present disclosure may include a transparent conductive material, a semitransparent conductive material, or an opaque conductive material. For example, the transparent or semitransparent conductive material may include indium tin oxide (ITO) or indium zinc oxide (IZO), but aspects of the present disclosure are not limited thereto. The opaque conductive material may include gold (Au), silver (Ag), platinum (Pt), palladium (Pd), molybdenum (Mo), magnesium (Mg), carbon, or Ag containing glass frit, or may include an alloy thereof, but aspects of the present disclosure are not limited thereto. For example, the first electrode layer 212 may include Ag having low resistivity, to enhance an electrical characteristic and/or a vibration characteristic of the active vibration part 211. For example, the carbon may include a carbon material including graphite, carbon black, ketjen black, and carbon nano tube, but aspects of the present disclosure are not limited thereto.

The second electrode layer 213 may be disposed at a second surface (or a rear surface), which is different from (or opposite to) the first surface, of the active vibration part 211. For example, the second electrode layer 213 may have a common electrode form which is disposed at the whole second surface of the active vibration part 211. For example, the second electrode layer 213 may have substantially the same a shape as that of the active vibration part 211, but aspects of the present disclosure are not limited thereto. The second electrode layer 213 according to an aspect of the present disclosure may include a transparent conductive material, a semitransparent conductive material, or an opaque conductive material. For example, the second electrode layer 213 may include the same material as that of the first electrode layer 212, but aspects of the present disclosure are not limited thereto. As another aspect of the present disclosure, the second electrode layer 213 may include a material which differs from that of the first electrode layer 212.

When a certain voltage is applied to the first electrode layer 212 and the second electrode layer 213, Maxwell stress P expressed as Equation 1 may be applied to the active vibration part 211, based on a coulombic force, but aspects of the present disclosure are not limited thereto. For example, the contraction and/or expansion of the active vibration part 211 and restoration of a balance state thereof may be alternately repeated by the Maxwell stress P based on the coulombic force based on a driving voltage (or a vibration driving signal or a voice signal) applied to the first electrode layer 212 and the second electrode layer 213. For example, the active vibration part 211 may vibrate based on a vertical-direction vibration and a horizontal-direction vibration by the first electrode layer 212 and the second electrode layer 213. For example, a displacement (or vibration or driving) of a vibration member (or a vibration plate or a vibration object) may increase based on the contraction and/or expansion of the active vibration part 211 in the horizontal direction, and thus, a vibration characteristic of a vibration apparatus may be more enhanced.

The active vibration device 210 according to an aspect of the present disclosure may further include a first cover member 215 and a second cover member 217.

The first cover member 215 may be disposed at the first surface of the active vibration device 210. For example, the first cover member 215 may be configured to cover the first electrode layer 212. Accordingly, the first cover member 215 may protect the first electrode layer 212.

The second cover member 217 may be disposed at the second surface of the active vibration device 210. For example, the second cover member 217 may be configured to cover the second electrode layer 213. Accordingly, the second cover member 217 may protect the second electrode layer 213.

Each of the first cover member 215 and the second cover member 217 according to an aspect of the present disclosure may include one or more materials of plastic, fiber, carbon, and wood, but aspects of the present disclosure are not limited thereto. For example, each of the first cover member 215 and the second cover member 217 may be a polyimide film or a polyethylene terephthalate film, but aspects of the present disclosure are not limited thereto.

The first cover member 215 according to an aspect of the present disclosure may be connected with or coupled to the first electrode layer 212 by using a first adhesive layer 214. For example, the first cover member 215 may be connected with or coupled to the first electrode layer 212 by a film laminating process using the first adhesive layer 214.

The second cover member 217 according to an aspect of the present disclosure may be connected with or coupled to the second electrode layer 213 by using a second adhesive layer 216. For example, the second cover member 217 may be connected with or coupled to the second electrode layer 213 by a film laminating process using the second adhesive layer 216.

The first adhesive layer 214 may be disposed between the first electrode layer 212 and the first cover member 215. The second adhesive layer 216 may be disposed between the second electrode layer 213 and the second cover member 217. For example, the first adhesive layer 214 and the second adhesive layer 216 may be provided between the first cover member 215 and the second cover member 217 to completely surround the active vibration part 211, the first electrode layer 212, and the second electrode layer 213. For example, the active vibration part 211, the first electrode layer 212, and the second electrode layer 213 may be buried or embedded between the first adhesive layer 214 and the second adhesive layer 216.

Each of the first adhesive layer 214 and the second adhesive layer 216 according to an aspect of the present disclosure may include an electrical insulating material which has adhesive properties and is capable of compression and decompression. For example, each of the first adhesive layer 214 and the second adhesive layer 216 may include epoxy resin, acrylic resin, silicone resin, or urethane resin, but aspects of the present disclosure are not limited thereto.

One of the first cover member 215 and the second cover member 217 may be attached on or coupled to (or connected with) a vibration member (or a vibration plate or a vibration object) by an adhesive member.

According to an aspect of the present disclosure, one of the first cover member 215 and the second cover member 217 may be attached on or coupled to (or connected with) the vibration member (or the vibration plate or the vibration object) by using the adhesive member. For example, as described above with reference to FIGS. 1 to 8, one of the first cover member 215 and the second cover member 217 may be attached on or coupled to (or connected with) the vibration member 100 by using an adhesive member 150.

The active vibration device 210 according to an aspect of the present disclosure may be electrically connected with a signal cable 271.

The signal cable 271 may be electrically connected with the first electrode layer 212 and the second electrode layer 213 of the active vibration device 210 and may supply the active vibration device 210 with a driving voltage (or a vibration driving signal or a voice signal) provided from a sound processing circuit. The signal cable 271 according to an aspect of the present disclosure may include a first line 271a electrically connected with the first electrode layer 212 and a second line 271b electrically connected with the second electrode layer 213. For example, the signal cable 271 may be configured as a flexible printed circuit cable, a flexible flat cable, a single-sided flexible printed circuit, a single-sided flexible printed circuit board (PCB), a flexible multi-layer printed circuit, or a flexible multi-layer PCB, but aspects of the present disclosure are not limited thereto.

The sound processing circuit may perform control so that ON where a driving voltage is applied and OFF where the driving voltage is not applied are alternately performed, based on sound data supplied from an external sound data generating circuit unit. The driving voltage may include a positive (+) driving voltage and a negative (−) driving voltage. For example, the positive (+) driving voltage may be supplied to the first electrode layer 212 through the first line 271a of the signal cable 271. The negative (−) driving voltage may be supplied to the second electrode layer 213 through the second line 271b of the signal cable 271. According to an aspect of the present disclosure, the signal cable 271 may be configured to be transparent, semitransparent, or opaque.

The active vibration device 210 according to an aspect of the present disclosure may include a dielectric elastomer which is better in availability than a piezoelectric material having a fragile characteristic and is good in restoring force corresponding to contraction and expansion based on a vibration, and thus, may be implemented as a thin film type. Accordingly, the active vibration device 210 may be bent in a shape corresponding to a shape of a vibration member or a vibration object. For example, when the active vibration device 210 is connected with or coupled to a vibration member including various curved portions by using the adhesive member 150, the active vibration device 210 may be bent in a curved shape along a shape of the curved portion of the vibration member 100, and despite being bent in a curved shape, reliability against damage or breakdown may not be reduced.

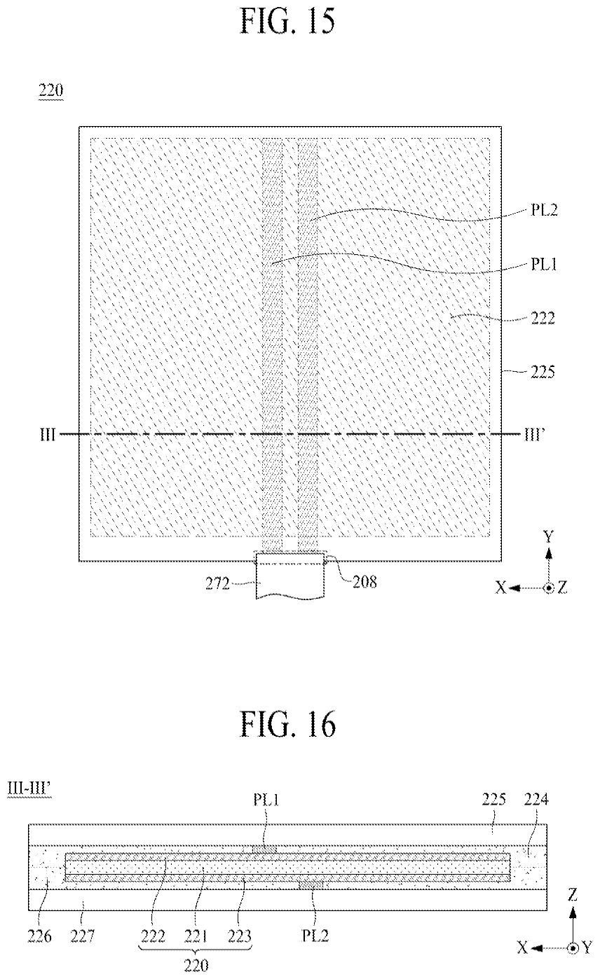

FIG. 15 illustrates a passive vibration device according to an aspect of the present disclosure. FIG. 16 is a cross-sectional view taken along line III-III′ illustrated in FIG. 15 according to an aspect of the present disclosure.

Referring to FIGS. 15 and 16, the passive vibration device 220 according to an aspect of the present disclosure may be an energy generating apparatus, an energy producing apparatus, an energy generator, an energy converter, an energy generating device, an energy producing device, an energy conversion device, a flexible energy generating apparatus, a flexible energy producing apparatus, a flexible energy generator, a flexible energy converter, a flexible energy generating device, a flexible energy producing device, a flexible energy conversion device, a piezoelectric-type energy generating apparatus, a piezoelectric-type energy producing apparatus, a piezoelectric-type energy generator, a piezoelectric-type energy converter, a piezoelectric-type energy generating device, a piezoelectric-type energy producing device, a piezoelectric-type energy conversion device, or an energy harvester, but aspects of the present disclosure are not limited thereto.

The passive vibration device 220 may include a tetragonal shape which has a first length parallel to a first direction X and a second length parallel to a second direction Y. For example, the active vibration device 220 may have a square shape where the first length is equal to the second length, or may have a rectangular shape where one of the first length and the second length is relatively long, but aspects of the present disclosure are not limited thereto.

The passive vibration device 220 according to an aspect of the present disclosure may include a passive vibration part 221, a first electrode layer 222, and a second electrode layer 223.

The passive vibration part 221 may include a piezoelectric material or an electroactive material having a piezoelectric effect. According to an aspect of the present disclosure, the passive vibration part 221 may include a piezoelectric material. For example, the piezoelectric material may have a characteristic where pressure or twisting is applied to a crystalline structure by an external force, a potential difference occurs due to dielectric polarization caused by a relative position change of a positive (+) ion and a negative (−) ion, and a vibration is generated by an electric field based on a voltage applied thereto. The passive vibration part 221 may be a piezoelectric layer, a piezoelectric material layer, an electroactive layer, a vibration part, a piezoelectric material portion, an electroactive part, a piezoelectric structure material, a piezoelectric composite layer, a piezoelectric composite, or a piezoelectric ceramic composite, but aspects of the present disclosure are not limited thereto. The passive vibration part 221 may include a transparent, semitransparent, or opaque piezoelectric material, and thus, the passive vibration part 221 may be transparent, semitransparent, or opaque.

Each of the active vibration part 211 and the passive vibration part 221 may comprise an inorganic material portion having a dielectric elastomer or a piezoelectric characteristic. At least one of the active vibration part 211 and the passive vibration part 221 may comprise a plurality of inorganic material portions having a piezoelectric characteristic and an organic material portion between the plurality of inorganic material portions. The passive vibration part 221 may include an inorganic material portion. The inorganic material portion may include a piezoelectric material, a composite piezoelectric material, or an electroactive material, which includes a piezoelectric effect.

The passive vibration part 221 according to an aspect of the present disclosure may include a ceramic-based material for implementing a relatively strong vibration, or may include a piezoelectric ceramic having a perovskite-based crystalline structure. The perovskite crystalline structure may have a piezoelectric effect and an inverse piezoelectric effect, and may be a plate-shaped structure having orientation. The perovskite crystalline structure may be represented by a chemical formula “ABO₃”. In the chemical formula, “A” may include a divalent metal element, and “B” may include a tetravalent metal element. For example, in the chemical formula “ABO₃”, “A” and “B” may be cations, and “O” may be anions. For example, the chemical formula “ABO₃” may include one or more of lead(II) titanate (PbTiO₃), lead zirconate (PbZrO₃), lead zirconate titanate (PbZrTiO₃), barium titanate (BaTiO₃), and strontium titanate (SrTiO₃), but aspects of the present disclosure are not limited thereto.

The piezoelectric ceramic may include single crystalline ceramic having a single crystalline structure, or may include a ceramic material or polycrystalline ceramic having a polycrystalline structure. A piezoelectric material of the single crystalline ceramic may include α-AlPO₄, α-SiO₂, LiNbO₃, Tb₂(MoO₄)₃, Li₂B₄O₇, or ZnO, but aspects of the present disclosure are not limited thereto. A piezoelectric material of the polycrystalline ceramic may include a lead zirconate titanate (PZT)-based material including lead (Pb), zirconium (Zr), and titanium (Ti) or may include a lead zirconate nickel niobate (PZNN)-based material including lead (Pb), zirconium (Zr), nickel (Ni), and niobium (Nb), but aspects of the present disclosure are not limited thereto.

As another aspect of the present disclosure, the passive vibration part 221 may include at least one of CaTiO₃, BaTiO₃, and SrTiO₃ without Pb, but aspects of the present disclosure are not limited thereto.

The first electrode layer 222 may be disposed at a first surface (or an upper surface) of the passive vibration part 221. For example, the first electrode layer 222 may have a common electrode form which is disposed at the whole first surface of the passive vibration part 221. For example, the first electrode layer 222 may have substantially the same a shape as that of the passive vibration part 221, but aspects of the present disclosure are not limited thereto.

The first electrode layer 222 according to an aspect of the present disclosure may include a transparent conductive material, a semitransparent conductive material, or an opaque conductive material. For example, the transparent or semitransparent conductive material may include indium tin oxide (ITO) or indium zinc oxide (IZO), but aspects of the present disclosure are not limited thereto. The opaque conductive material may include gold (Au), silver (Ag), platinum (Pt), palladium (Pd), molybdenum (Mo), magnesium (Mg), carbon, or Ag containing glass frit, or may include an alloy thereof, but aspects of the present disclosure are not limited thereto. For example, the first electrode layer 222 may include Ag having low resistivity, to enhance an electrical characteristic and/or a vibration characteristic of the passive vibration part 221. For example, the carbon may include a carbon material including graphite, carbon black, ketjen black, and carbon nano tube, but aspects of the present disclosure are not limited thereto.

The second electrode layer 223 may be disposed at a second surface (or a rear surface), which is different from (or opposite to) the first surface, of the passive vibration part 221. For example, the second electrode layer 223 may have a common electrode form which is disposed at the whole second surface of the passive vibration part 221. For example, the second electrode layer 223 may have substantially the same shape as that of the passive vibration part 221, but aspects of the present disclosure are not limited thereto. The second electrode layer 223 according to an aspect of the present disclosure may include a transparent conductive material, a semitransparent conductive material, or an opaque conductive material. For example, the second electrode layer 223 may include the same material as that of the first electrode layer 222, but aspects of the present disclosure are not limited thereto. As another aspect of the present disclosure, the second electrode layer 223 may include a material which differs from that of the first electrode layer 222.

When deformation is performed by a physical vibration or force in a certain temperature atmosphere or a temperature atmosphere which is changed from a high temperature to a room temperature, a voltage may be generated, and thus, electrical energy may be generated. For example, when the passive vibration part 221 is deformed by a vibration or a force applied from the outside, a voltage may be generated based on a piezoelectric effect (or a piezoelectric characteristic) of a piezoelectric material and the deformation and restoration of the passive vibration part 221 may be alternately repeated, and thus, electrical energy may be generated and accumulated.

The passive vibration device 220 according to an aspect of the present disclosure may further include a first cover member 225 and a second cover member 227.

The first cover member 225 may be disposed at the first surface of the passive vibration device 220. For example, the first cover member 225 may be configured to cover the first electrode layer 222. Accordingly, the first cover member 225 may protect the first electrode layer 222.

The second cover member 227 may be disposed at the second surface of the passive vibration device 220. For example, the second cover member 227 may be configured to cover the second electrode layer 223. Accordingly, the second cover member 227 may protect the second electrode layer 223.

Each of the first cover member 225 and the second cover member 227 according to an aspect of the present disclosure may include one or more materials of plastic, fiber, carbon, and wood, but aspects of the present disclosure are not limited thereto. For example, each of the first cover member 225 and the second cover member 227 may be a polyimide film or a polyethylene terephthalate film, but aspects of the present disclosure are not limited thereto.

The first cover member 225 according to an aspect of the present disclosure may be connected with or coupled to the first electrode layer 222 by using a first adhesive layer 224. For example, the first cover member 225 may be connected with or coupled to the first electrode layer 222 by a film laminating process using the first adhesive layer 224.

The second cover member 227 according to an aspect of the present disclosure may be connected with or coupled to the second electrode layer 223 by using a second adhesive layer 226. For example, the second cover member 227 may be connected with or coupled to the second electrode layer 223 by a film laminating process using the second adhesive layer 226.

The first adhesive layer 224 may be disposed between the first electrode layer 222 and the first cover member 225. The second adhesive layer 226 may be disposed between the second electrode layer 223 and the second cover member 227. For example, the first adhesive layer 224 and the second adhesive layer 226 may be provided between the first cover member 225 and the second cover member 227 to completely surround the passive vibration part 221, the first electrode layer 222, and the second electrode layer 223. For example, the passive vibration part 221, the first electrode layer 222, and the second electrode layer 223 may be buried or embedded between the first adhesive layer 224 and the second adhesive layer 226.

Each of the first adhesive layer 224 and the second adhesive layer 226 according to an aspect of the present disclosure may include an electrical insulating material which has adhesive properties and is capable of compression and decompression. For example, each of the first adhesive layer 224 and the second adhesive layer 226 may include epoxy resin, acrylic resin, silicone resin, or urethane resin, but aspects of the present disclosure are not limited thereto.

One of the first cover member 225 and the second cover member 227 may be attached on or coupled to (or connected with) a vibration member (or a vibration plate or a vibration object) by using an adhesive member.

According to an aspect of the present disclosure, one of the first cover member 225 and the second cover member 227 may be attached on or coupled to (or connected with) the vibration member (or the vibration plate or the vibration object) by using the adhesive member. For example, as described above with reference to FIGS. 1 to 8, one of the first cover member 225 and the second cover member 227 may be attached on or coupled to (or connected with) the vibration member 100 by using an adhesive member 150.

The passive vibration device 220 according to an aspect of the present disclosure may further include a first power output line PL1, a second power output line PL2, and a pad part 208.

The first power output line PL1 may be disposed in the first cover member 225. For example, the first power output line PL1 may be disposed between the first electrode layer 222 and the first cover member 225 and may be electrically connected with the first electrode layer 222. The first power output line PL1 may extend long in the second direction Y and may be electrically connected with a center portion of the first electrode layer 222. In an aspect of the present disclosure, the first power output line PL1 may be electrically connected with the first electrode layer 222 by using an anisotropic conductive film. In another aspect of the present disclosure, the first power output line PL1 may be electrically connected with the first electrode layer 222 through a conductive material (or particles) included in the first adhesive layer 224.

The second power output line PL2 may be disposed in the second cover member 227. For example, the second power output line PL2 may be disposed between the second electrode layer 223 and the second cover member 227 and may be electrically connected with the second electrode layer 223. The second power output line PL2 may extend long in the second direction Y and may be electrically connected with a center portion of the second electrode layer 223. In an aspect of the present disclosure, the second power output line PL2 may be electrically connected with the second electrode layer 223 by using an anisotropic conductive film. In another aspect of the present disclosure, the second power output line PL2 may be electrically connected with the second electrode layer 223 through a conductive material (or particles) included in the second adhesive layer 226.

According to an aspect of the present disclosure, the first power output line PL1 and the second power output line PL2 may be disposed not to overlap with each other. When the first power output line PL1 and the second power output line PL2 are disposed not to overlap with each other, a problem of a short circuit defect between the first power output line PL1 and the second power output line PL2 may be solved.

The pad part 208 may electrically connect the first power output line PL1 with the second power output line PL2. For example, the pad part 208 may be provided at one edge portion of one of the first cover member 225 and the second cover member 227 to be electrically connected with one side (or one end) of each of the first power output line PL1 and the second power output line PL2.

The pad part 208 according to an aspect of the present disclosure may include a first pad electrode electrically connected with one end (or one side) of the first power output line PL1 and a second pad electrode electrically connected with one end (or one side) of the second power output line PL2.

The first pad electrode may be disposed at one edge portion of one of the first cover member 225 and the second cover member 227 and may be connected with one end (or one side) of the first power output line PL1. For example, the first pad electrode may pass through one of the first cover member 225 and the second cover member 227 and may be electrically connected with the one end (or one side) of the first power output line PL1.

The second pad electrode may be disposed in parallel with the first pad electrode and may be connected with one end (or one side) of the second power output line PL2. For example, the second pad electrode may pass through one of the first cover member 225 and the second cover member 227 and may be electrically connected with the one end (or one side) of the second power output line PL2.

According to an aspect of the present disclosure, each of the first power output line PL1, the second power output line PL2, and the pad part 208 may be configured to be transparent, semitransparent, or opaque.

The pad part 208 according to an aspect of the present disclosure may be electrically connected with a signal cable 272.

The signal cable 272 may be electrically connected with the pad part 208 disposed in the passive vibration device 220 and may output electrical energy, generated by the passive vibration device 220, to the outside. The signal cable 272 according to an aspect of the present disclosure may include a first terminal electrically connected with the first pad electrode of the pad part 208 and a second terminal electrically connected with the second pad electrode of the pad part 208. For example, the signal cable 272 may be configured as a flexible printed circuit cable, a flexible flat cable, a single-sided flexible printed circuit, a single-sided flexible PCB, a flexible multi-layer printed circuit, or a flexible multi-layer PCB, but aspects of the present disclosure are not limited thereto. According to an aspect of the present disclosure, the signal cable 272 may be configured to be transparent, semitransparent, or opaque.

Electrical energy generated by the passive vibration device 220 may be transferred to a capacitor, included in the apparatus 10, through the signal cable 272. For example, the capacitor included in the apparatus 10 may store the electrical energy transferred from the passive vibration device 220, but aspects of the present disclosure are not limited thereto.

The passive vibration device 220 according to an aspect of the present disclosure may include a first portion having a piezoelectric characteristic and a second portion having flexibility, and the first portion and the second portion may be alternately repeated and connected with each other, whereby the passive vibration device 220 may be implemented as a thin film type. Accordingly, the passive vibration device 220 may be bent in a shape corresponding to a shape of a vibration member or a vibration object. For example, when the passive vibration device 220 is connected with or coupled to a vibration member including various curved portions by using the adhesive member 150, the passive vibration device 220 may be bent in a curved shape along a shape of the curved portion of the vibration member 100, and despite being bent in a curved shape, reliability against damage or breakdown may not be reduced.

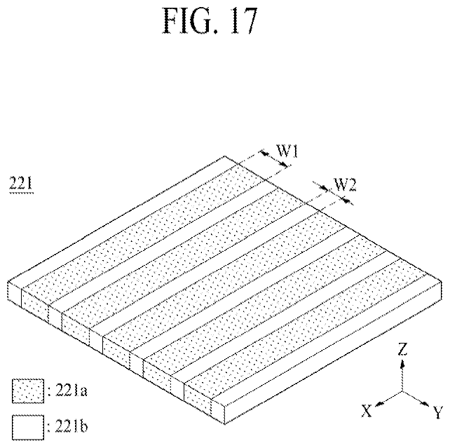

FIG. 17 illustrates a passive vibration part according to another aspect of the present disclosure.

Referring to FIG. 17, the passive vibration part 221 according to another aspect of the present disclosure may include a plurality of first portions 221a and a plurality of second portions 221b. For example, the plurality of first portions 221a and the plurality of second portions 221b may be alternately and repeatedly arranged in a first direction X (or a second direction Y). For example, the first direction X may be a widthwise direction of the passive vibration part 221, and the second direction Y may be a lengthwise direction of the passive vibration part 221 intersecting with the first direction X, but aspects of the present disclosure are not limited thereto. For example, the first direction X may be the lengthwise direction of the passive vibration part 221, and the second direction Y may be the widthwise direction of the passive vibration part 221.

A passive vibration device 220 according to another aspect of the present disclosure may be configured to have flexibility. For example, the passive vibration device 220 may be provided to be bent in a nonplanar surface including a curved surface.

Each of the plurality of first portions 221a may include an inorganic material portion. The inorganic material portion may include a piezoelectric material, a composite piezoelectric material, or an electroactive material, which has a piezoelectric effect, but aspects of the present disclosure are not limited thereto.

Each of the plurality of first portions 221a may include a ceramic-based material for generating a relatively strong vibration, or may include a piezoelectric ceramic having a perovskite-based crystalline structure. The perovskite crystalline structure may have a piezoelectric effect and/or an inverse piezoelectric effect, and may be a plate-shaped structure having orientation. The perovskite crystalline structure may be represented by a chemical formula “ABO₃”. In the chemical formula, “A” may include a divalent metal element, and “B” may include a tetravalent metal element. For example, in the chemical formula “ABO₃”, “A” and “B” may be cations, and “O” may be anions. For example, the first portions 221a may include one or more of lead(II) titanate (PbTiO₃), lead zirconate (PbZrO₃), lead zirconate titanate (PbZrTiO₃), barium titanate (BaTiO₃), and strontium titanate (SrTiO₃), but aspects of the present disclosure are not limited thereto.

A piezoelectric ceramic may include single crystalline ceramic having a single crystalline structure, or may include a ceramic material or polycrystalline ceramic having a polycrystalline structure. A piezoelectric material of the single crystalline ceramic may include α-AlPO₄, α-SiO₂, LiNbO₃, Tb₂(MoO₄)₃, Li₂B₄O₇, or ZnO, but aspects of the present disclosure are not limited thereto. A piezoelectric material of the polycrystalline ceramic may include a lead zirconate titanate (PZT)-based material including lead (Pb), zirconium (Zr), and titanium (Ti) or may include a lead zirconate nickel niobate (PZNN)-based material including lead (Pb), zirconium (Zr), nickel (Ni), and niobium (Nb), but aspects of the present disclosure are not limited thereto.

As another aspect of the present disclosure, the passive vibration part 221 may include at least one of CaTiO₃, BaTiO₃, and SrTiO₃ without Pb, but aspects of the present disclosure are not limited thereto.

Each of the plurality of first portions 221a according to an aspect of the present disclosure may be disposed between two adjacent second portions 221b of the plurality of second portions 221b, have a first width W1 parallel to the first direction X (or the second direction Y), and have a length parallel to the second direction Y (or the first direction X). Each of the plurality of second portions 221b may have a second width W2 parallel to the first direction X (or the second direction Y) and may have a length parallel to the second direction Y (or the first direction X). The first width W1 may be equal to or different from the second width W2. For example, the first width W1 may be greater than the second width W2. For example, the first portion 221a and the second portion 221b may include a line shape or a stripe shape having the same size or different sizes.

In the passive vibration part 221, the plurality of first portions 221a and the plurality of second portions 221b may be disposed (or arranged) on the same plane (or the same layer). Each of the plurality of first portions 221a may be provided to fill a gap between two adjacent second portions 221b, and thus, may be connected with or attached on an adjacent first portion 221a. Accordingly, the passive vibration part 221a may extend to have a desired size or length, based on lateral coupling (or connection) between the first portion 221a and the second portion 221b.

In the passive vibration part 221, a width W2 of each of the plurality of second portions 221b may decrease progressively toward both edge portions (or both ends) of the passive vibration part 221 from a center portion of the passive vibration part 221.

According to an aspect of the present disclosure, when the passive vibration part 221 vibrates in a vertical direction Z (or a thickness direction), a second portion 221b having a largest width W2 among the plurality of second portions 221b may be disposed at a portion on which a largest stress concentrates. When the passive vibration part 221 vibrates in the vertical direction Z, a second portion 221b having a smallest width W2 among the plurality of second portions 221b may be disposed at a portion on which a smallest stress concentrates. For example, the second portion 221b having the largest width W2 among the plurality of second portions 221b may be disposed at the center portion of the passive vibration part 221, and the second portion 221b having the smallest width W2 among the plurality of second portions 221b may be disposed at the both edge portions of the passive vibration part 221.

In the passive vibration part 221, the plurality of first portions 221a may have different sizes (or widths). For example, a size (or a width) of each of the plurality of first portions 221a may decrease or increase progressively toward the both edge portions (or the both ends) of the passive vibration part 221 from the center portion of the passive vibration part 221.

Each of the plurality of second portions 221b may be disposed between the plurality of first portions 221a. Therefore, in the passive vibration part 221, vibration energy based on a link in a unit lattice of the first portion 221a may be increased by the second portion 221b, and thus, a vibration characteristic may increase and a piezoelectric characteristic and flexibility may be secured. For example, the second portion 221b may include one of an epoxy-based polymer, an acrylic-based polymer, and a silicone-based polymer, but aspects of the present disclosure are not limited thereto.

Each of the plurality of second portions 221b according to an aspect of the present disclosure may include an organic material portion. For example, each of the organic material portions may be disposed between two adjacent inorganic material portions of the plurality of inorganic material portions, and thus, may absorb an impact applied to a corresponding inorganic material portion (or a first portion), a stress concentrating on the inorganic material portion may be released to enhance the durability of the passive vibration part 221, and flexibility may be provided to the passive vibration part 221.

The second portion 221b according to an aspect of the present disclosure may have modulus (or young's modulus) and viscoelasticity which are lower than those of the first portion 221a, and thus, may enhance the reliability of the first portion 221a which is vulnerable to an impact due to a fragile characteristic thereof. For example, the second portion 221b may include a material which has a loss coefficient of 0.01 to 1 and a modulus of 0.1 Gpa to 10 Gpa (Gigapascal).

The organic material portion included in the second portion 221b may include an organic material, an organic polymer, an organic piezoelectric material, or an organic non-piezoelectric material having a flexible characteristic compared to the inorganic material portion which is the first portion 221a. For example, the second portion 221b may be referred to as an adhesive portion, a flexible portion, a bending portion, a damping portion, or a ductile portion, or the like, but aspects of the present disclosure are not limited thereto.

The plurality of first portions 221a and the plurality of second portions 221b may be disposed on (or connected to) the same plane, and thus, the passive vibration part 221 according to an aspect of the present aspect may have a single thin film form. For example, the passive vibration part 221 may have a structure where the plurality of first portions 221a are connected to one side thereof. For example, the passive vibration part 221 may have a structure where the plurality of first portions 221a are connected in all of the passive vibration part 221. For example, the passive vibration part 221 may be vibrated in a vertical direction by the first portion 221a having a vibration characteristic and may be bent in a curved shape by the second portion 221b having flexibility. Also, in the passive vibration part 221 according to an aspect of the present disclosure, a size of the first portion 221a and a size of the second portion 221b may be adjusted based on a piezoelectric characteristic and flexibility needed for the passive vibration part 221. For example, in the passive vibration part 221 requiring a piezoelectric characteristic rather than flexibility, a size of the first portion 221a may be adjusted to be greater than that of the second portion 221b. In another aspect of the present disclosure, in the passive vibration part 221 requiring flexibility rather than a piezoelectric characteristic, a size of the second portion 221b may be adjusted to be greater than that of the first portion 221a. Accordingly, a size of the passive vibration part 221 may be adjusted based on a desired characteristic, and thus, the passive vibration part 221 may be easily designed.

The passive vibration part 221 according to another aspect of the present disclosure may include a plurality of first portions 221a which are spaced apart from one another in the first direction X and the second direction Y and a second portion 221b disposed between the plurality of first portions 221a.

The plurality of first portions 221a may be disposed apart from one another in each of the first direction X and the second direction Y. For example, the plurality of first portions 221a may have a hexahedral shape having the same size and may be arranged in a lattice shape. Each of the plurality of first portions 221a may include substantially the same material as that of the first portion 221a described above with reference to FIG. 17, and thus, like reference numerals refer to like elements and their repeated descriptions are omitted.

The second portion 221b may be disposed between the plurality of first portions 221a in each of the first direction X and the second direction Y. The second portion 221b may be configured to fill a gap between two adjacent first portions 221a or to surround each of the plurality of first portions 221a, and thus, may be connected to or attached on an adjacent first portion 221a. According to an aspect of the present disclosure, a width of a second portion 11b disposed between two first portions 221a adjacent to each other in the first direction X may be the same as or different from that of the first portion 221a, and a width of a second portion 221b disposed between two first portions 221a adjacent to each other in the second direction Y may be the same as or different from that of the first portion 221a. The second portion 221b may include substantially the same organic material as that of the second portion 221b described above with reference to FIG. 17, and thus, like reference numerals refer to like elements and their repeated descriptions are omitted.

In the passive vibration part 221 according to another aspect of the present disclosure, each of the plurality of first portions 221a may have a circular flat structure. For example, each of the plurality of first portions 221a may have a circular plate shape, but aspects of the present disclosure are not limited thereto. For example, each of the plurality of first portions 221a may have a dot shape including an oval shape, a polygonal shape, or a donut shape. The passive vibration part 221 may include a plurality of first portions 221a, which are spaced apart from one another in the first direction X and the second direction Y, and a second portion 221b between the plurality of first portions 221a.

In the passive vibration part 221 according to another aspect of the present disclosure, each of the plurality of first portions 221a may have a triangular flat structure. For example, each of the plurality of first portions 221a may have a triangular plate shape.

According to another aspect of the present disclosure, four adjacent first portions 221a of the plurality of first portions 221a may be arranged adjacent to one another to form a tetragonal shape (or a square shape). A vertex of each of four adjacent first portions 221a forming a tetragonal shape may be disposed adjacent to a center portion (or a middle portion) of a tetragonal shape.

In the passive vibration part 221 according to another aspect of the present disclosure, each of the plurality of first portions 221a may have a hexagonal flat structure. For example, each of the plurality of first portions 221a may have a hexagonal plate shape.

According to another aspect of the present disclosure, six adjacent first portions 221a of the plurality of first portions 221a may be arranged adjacent to one another to form a hexagonal (or a regular hexagonal shape). A vertex of each of six adjacent first portions 221a forming a hexagonal shape may be disposed adjacent to a center portion (or a middle portion) of a hexagonal shape.

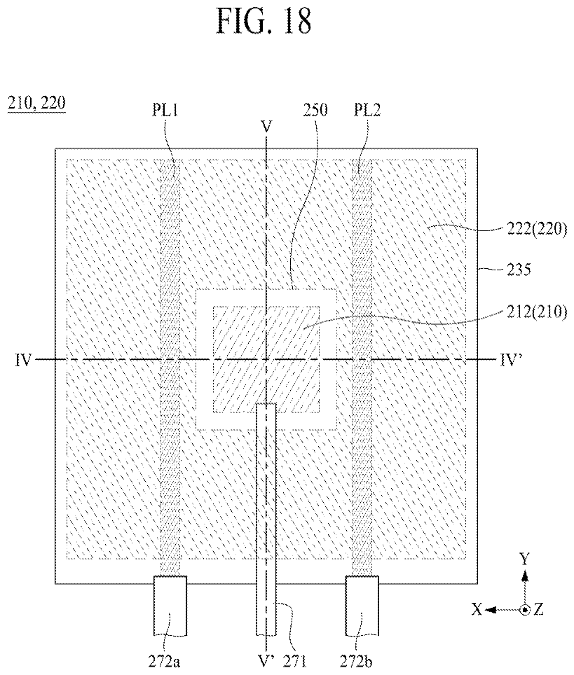

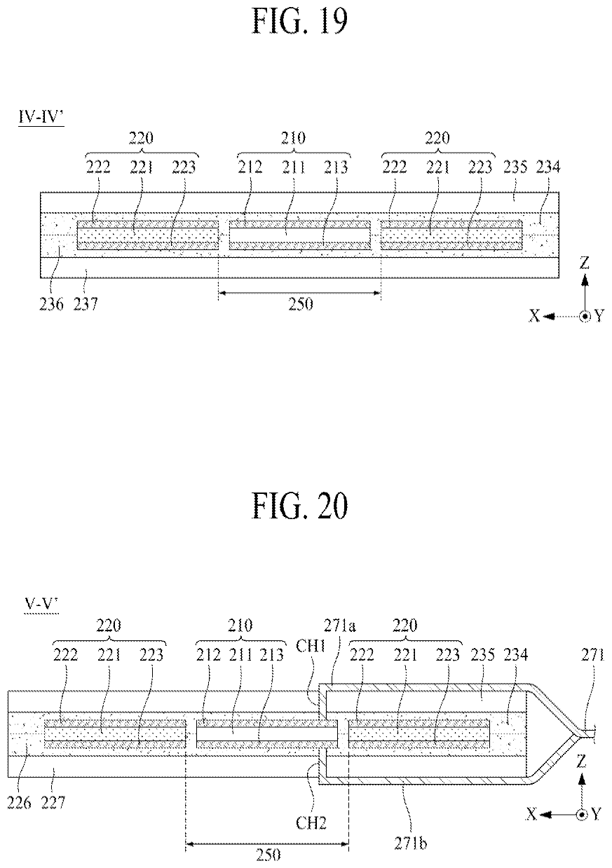

FIG. 18 illustrates an active vibration device and a passive vibration device 220 according to another aspect of the present disclosure. FIG. 19 is a cross-sectional view taken along line IV-IV′ illustrated in FIG. 18 according to another aspect of the present disclosure. FIG. 20 is a cross-sectional view taken along line V-V′ illustrated in FIG. 18 according to another aspect of the present disclosure. FIGS. 18 to 20 illustrate a configuration of each of the active vibration device and the passive vibration device in the apparatus described above with reference to FIGS. 1 to 17. In the following description, therefore, like elements other than a configuration of each of an active vibration device and a passive vibration device and relevant elements are referred to by like reference numerals, and repeated descriptions thereof are omitted or will be briefly given.

Referring to FIGS. 18 to 20, the active vibration device 210 and the passive vibration device 220 according to another aspect of the present disclosure may be implemented or provided as a single module type. For example, the active vibration device 210 and the passive vibration device 220 according to another aspect of the present disclosure may be implemented or provided as a single film type.

The active vibration device 210 may include a tetragonal shape which has a first length parallel to a first direction X and a second length parallel to a second direction Y. For example, the active vibration device 210 may include a square shape where the first length is equal to the second length, or the active vibration device 210 may include a rectangular shape where one of the first length and the second length is relatively long, but aspects of the present disclosure are not limited thereto.

The passive vibration device 220 may include a shape which surrounds a periphery of the active vibration device 210. The passive vibration device 220 may include at least one opening region, for example, an opening region 250, having a size which is greater than that of the active vibration device 210, in a center portion thereof. The opening region 250 may be spaced apart from the active vibration device 210 by a certain interval and may be provided to surround the active vibration device 210. For example, the passive vibration device 220 may have a size which is greater than that of the active vibration device 210 and may include the opening region 250, having a size which is greater than that of the active vibration device 210 and corresponding to a shape of the active vibration device 210, in the center portion thereof. For example, the active vibration device 210 may be disposed in the opening region 250 of the passive vibration device 220, and thus, may not overlap with the passive vibration device 220 one-dimensionally.

The active vibration device 210 may include an active vibration part 211, a first electrode layer 212, and a second electrode layer 213. Also, the passive vibration device 220 may include a passive vibration part 221, a first electrode layer 222, and a second electrode layer 223. For example, the passive vibration part 221, the first electrode layer 222, and the second electrode layer 223 of the passive vibration device 220 may include the opening region 250. The active vibration part 211, the first electrode layer 212, and the second electrode layer 213 of the active vibration device 210 may be disposed in the opening region 250 of the passive vibration device 220, and thus, may not overlap with the passive vibration part 221, the first electrode layer 222, and the second electrode layer 223 of the passive vibration device 220 one-dimensionally. For example, the active vibration part 211, the first electrode layer 212, and the second electrode layer 213 of the active vibration device 210 may be spaced apart from and electrically disconnected from the passive vibration part 221, the first electrode layer 222, and the second electrode layer 223 of the passive vibration device 220.

The active vibration device 210 may include an electroactive material or a piezoelectric material having a piezoelectric effect. According to an aspect of the present disclosure, the active vibration part 211 may include an electroactive material. For example, the electroactive material may have a characteristic where a coulombic force acts based on a voltage applied to electrodes disposed at both surfaces, and simultaneously, a vibration is generated as Maxwell Stress is applied. The active vibration part 211 may include a transparent, semitransparent, or opaque piezoelectric material, and thus, the active vibration part 211 may be transparent, semitransparent, or opaque.

The passive vibration part 221 of the passive vibration device 220 may include a piezoelectric material or an electroactive material having a piezoelectric effect. According to an aspect of the present disclosure, the passive vibration part 221 may include a piezoelectric material. For example, the piezoelectric material may have a characteristic where pressure or twisting is applied to a crystalline structure by an external force, a potential difference occurs due to dielectric polarization caused by a relative position change of a positive (+) ion and a negative (−) ion, and a vibration is generated by an electric field based on a voltage applied thereto. The passive vibration part 221 may be a piezoelectric layer, a piezoelectric material layer, an electroactive layer, a vibration part, a piezoelectric material portion, an electroactive part, a piezoelectric structure material, a piezoelectric composite layer, a piezoelectric composite, or a piezoelectric ceramic composite, but aspects of the present disclosure are not limited thereto. The passive vibration part 221 may include a transparent, semitransparent, or opaque piezoelectric material, and thus, may be transparent, semitransparent, or opaque.

According to another aspect of the present disclosure, the active vibration device 210 and the passive vibration device 220 may further include a first cover member 235 and a second cover member 237.

The first cover member 235 may be disposed at a first surface of each of the active vibration device 210 and the passive vibration device 220 in common. For example, the first cover member 235 may be configured to cover the first electrode layer 212 of the active vibration device 210 and the first electrode layer 222 of the passive vibration device 220 in common. Accordingly, the first cover member 235 may protect the first electrode layer 212 of the active vibration device 210 and the first electrode layer 222 of the passive vibration device 220.

The second cover member 237 may be disposed at a second surface of each of the active vibration device 210 and the passive vibration device 220 in common. For example, the second cover member 237 may be configured to cover the second electrode layer 213 of the active vibration device 210 and the second electrode layer 223 of the passive vibration device 220 in common. Accordingly, the second cover member 237 may protect the second electrode layer 213 of the active vibration device 210 and the second electrode layer 223 of the passive vibration device 220.

Each of the first cover member 235 and the second cover member 237 according to an aspect of the present disclosure may include one or more materials of plastic, fiber, carbon, and wood, but aspects of the present disclosure are not limited thereto. For example, each of the first cover member 235 and the second cover member 237 may be a polyimide film or a polyethylene terephthalate film, but aspects of the present disclosure are not limited thereto.

The first cover member 235 according to another aspect of the present disclosure may be connected with or coupled to the first electrode layer 212 of the active vibration device 210 and the first electrode layer 222 of the passive vibration device 220 by using a first adhesive layer 234. For example, the first cover member 235 may be connected with or coupled to the first electrode layer 212 of the active vibration device 210 and the first electrode layer 222 of the passive vibration device 220 by a film laminating process using the first adhesive layer 234.

The second cover member 237 according to another aspect of the present disclosure may be connected with or coupled to the second electrode layer 213 of the active vibration device 210 and the second electrode layer 223 of the passive vibration device 220 by using a second adhesive layer 236. For example, the second cover member 237 may be connected with or coupled to the second electrode layer 213 of the active vibration device 210 and the second electrode layer 223 of the passive vibration device 220 by a film laminating process using the second adhesive layer 236.

The first adhesive layer 234 may be disposed between the first electrode layer 212 of the active vibration device 210, the first electrode layer 222 of the passive vibration device 220, and the first cover member 235. The second adhesive layer 236 may be disposed between the second electrode layer 213 of the active vibration device 210, the second electrode layer 223 of the passive vibration device 220, and the second cover member 237. For example, the first adhesive layer 234 and the second adhesive layer 236 may be provided between the first cover member 235 and the second cover member 237 to completely surround the active vibration part 211, the passive vibration part 221, the first electrode layers 212 and 222, and the second electrode layers 213 and 223. For example, the active vibration part 211, the passive vibration part 221, the first electrode layers 212 and 222, and the second electrode layers 213 and 223 may be buried or embedded between the first adhesive layer 234 and the second adhesive layer 236.

Each of the first adhesive layer 234 and the second adhesive layer 236 according to an aspect of the present disclosure may include an electrical insulating material which has adhesive properties and is capable of compression and decompression. For example, each of the first adhesive layer 234 and the second adhesive layer 236 may include epoxy resin, acrylic resin, silicone resin, or urethane resin, but aspects of the present disclosure are not limited thereto.

One of the first cover member 235 and the second cover member 237 may be attached on or coupled to (or connected with) a vibration member (or a vibration plate or a vibration object) by using an adhesive member.

According to an aspect of the present disclosure, one of the first cover member 235 and the second cover member 237 may be attached on or coupled to (or connected with) the vibration member (or the vibration plate or the vibration object) by using the adhesive member. For example, as described above with reference to FIGS. 1 to 8, one of the first cover member 235 and the second cover member 237 may be attached on or coupled to (or connected with) the vibration member 100 by using an adhesive member 150.

According to another aspect of the present disclosure, the active vibration device 210 may be electrically connected with a first signal cable 271. Also, the passive vibration device 220 may be electrically connected with second signal cables 272a and 272b.

The first signal cable 271 may be electrically connected with the first electrode layer 212 and the second electrode layer 213 of the active vibration device 210 and may supply the active vibration device 210 with a driving voltage (or a vibration driving signal or a voice signal) provided from a sound processing circuit. The first signal cable 271 according to another aspect may include a first line 271a electrically connected with the first electrode layer 212 and a second line 271b electrically connected with the second electrode layer 213.

According to another aspect of the present disclosure, the first cover member 235 and the second cover member 237 may further include at least one hole CH1 and CH2 through which the first signal cable 271 passes, respectively. Each of the holes CH1 and CH2 may be a contact hole, but aspects of the present disclosure are not limited thereto.

The first cover member 235 may include a first hole CH1. For example, the first cover member 235 may include the first hole CH1 which passes through the first cover member 235, so that the first electrode layer 212 of the active vibration device 210 is electrically connected with the first line 271a of the first signal cable 271. For example, the first line 271a of the first signal cable 271 may be electrically connected with the first electrode layer 212 of the active vibration device 210 through the first hole CH1 of the first cover member 235.

The second cover member 237 may include a second hole CH2. For example, the second cover member 237 may include the second hole CH2 which passes through the second cover member 237, so that the second electrode layer 213 of the active vibration device 210 is electrically connected with the second line 271b of the first signal cable 271. For example, the second line 271b of the first signal cable 271 may be electrically connected with the second electrode layer 213 of the active vibration device 210 through the second hole CH2 of the second cover member 237.

The passive vibration device 220 according to another aspect of the present disclosure may further include a first power output line PL1 and a second power output line PL2.

The first power output line PL1 may be disposed in the first cover member 235. For example, the first power output line PL1 may be disposed between the first electrode layer 222 and the first cover member 235 and may be electrically connected with the first electrode layer 222. The first power output line PL1 may extend long in the second direction Y and may be electrically connected with a left portion or a right portion of the first electrode layer 222 with respect to a center portion of the first electrode layer 222 not to overlap with the active vibration device 210. For example, the first power output line PL1 may be electrically connected with a left portion of the first electrode layer 222.

The second power output line PL2 may be disposed in the second cover member 237. For example, the second power output line PL2 may be disposed between the second electrode layer 223 and the second cover member 237 and may be electrically connected with the second electrode layer 223. The second power output line PL2 may extend long in the second direction Y and may be electrically connected with a left portion or a right portion of the second electrode layer 223 with respect to a center portion of the second electrode layer 223 not to overlap with the active vibration device 210. For example, the second power output line PL2 may be electrically connected with a right portion of the second electrode layer 223.

According to another aspect of the present disclosure, the first power output line PL1 and the second power output line PL2 may be respectively disposed at the left portions or the right portions of the first electrode layer 222 and the second electrode layer 223 with respect to the center portions of the first electrode layer 222 and the second electrode layer 223, and thus, a problem of a short circuit defect between the first power output line PL1 and the second power output line PL2 may be solved.

According to another aspect of the present disclosure, each of the first power output line PL1 and the second power output line PL2 may be electrically connected with the second signal cables 272a and 272b at one edge portion of one of the first cover member 235 and the second cover member 237. For example, the first power output line PL1 may be electrically connected with the second signal cable 272a at one edge portion of the first cover member 235. Also, the second power output line PL2 may be electrically connected with the second signal cable 272b at one edge portion of the second cover member 237.

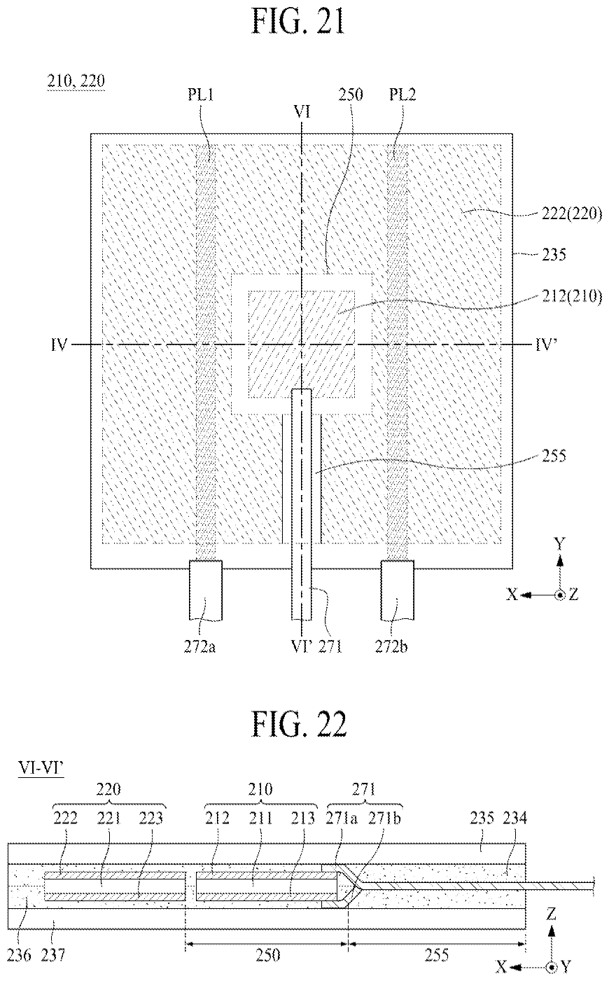

FIG. 21 illustrates an active vibration device and a passive vibration device according to another aspect of the present disclosure. FIG. 22 is a cross-sectional view taken along line VI-VI′ illustrated in FIG. 21 according to another aspect of the present disclosure. FIGS. 21 and 22 illustrate an aspect implemented by modifying a configuration of each of the active vibration device and the passive vibration device in the apparatus described above with reference to FIGS. 1 to 17. In the following description, therefore, like elements other than a configuration of each of an active vibration device and a passive vibration device and relevant elements are referred to by like reference numerals, and repeated descriptions thereof are omitted or will be briefly given. Also, in FIG. 21, a cross-sectional view taken along line IV-IV′ illustrates substantially the same configuration as FIG. 19, and thus, the illustration is omitted.

Referring to FIGS. 21 and 22, the active vibration device 210 and the passive vibration device 220 according to another aspect of the present disclosure may be implemented or provided as a single module. For example, the active vibration device 210 and the passive vibration device 220 according to another aspect of the present disclosure may be implemented or provided as a single film type. The active vibration device 210 and the passive vibration device 220 may further include a first cover member 235 and a second cover member 237. Also, the active vibration device 210 may be electrically connected with a first signal cable 271. Also, the passive vibration device 220 may be electrically connected with second signal cables 272a and 272b.

The active vibration device 210 may include a tetragonal shape which has a first length parallel to a first direction X and a second length parallel to a second direction Y. For example, the active vibration device 210 may include a square shape where the first length is equal to the second length, or the active vibration device 210 may include a rectangular shape where one of the first length and the second length is relatively long, but aspects of the present disclosure are not limited thereto.

The passive vibration device 220 may include a shape which surrounds a periphery of the active vibration device 210. The passive vibration device 220 may include an opening region 250, having a size which is greater than that of the active vibration device 210, in a center portion thereof. The opening region 250 may be spaced apart from the active vibration device 210 by a certain interval and may be provided to surround the active vibration device 210. For example, the passive vibration device 220 may have a size which is greater than that of the active vibration device 210 and may include the opening region 250, having a size which is greater than that of the active vibration device 210 and corresponding to a shape of the active vibration device 210, in the center portion thereof. For example, the active vibration device 210 may be disposed in the opening region 250 of the passive vibration device 220, and thus, may not overlap with the passive vibration device 220 one-dimensionally.

According to another aspect of the present disclosure, the passive vibration device 220 may further include a through region 255 through which the first signal cable 271 passes, so that the first signal cable 271 is connected with the active vibration device 210.

The first signal cable 271 may be electrically connected with the first electrode layer 212 and the second electrode layer 213 of the active vibration device 210 and may supply the active vibration device 210 with a driving voltage (or a vibration driving signal or a voice signal) provided from a sound processing circuit. The first signal cable 271 according to another aspect may include a first line 271a electrically connected with the first electrode layer 212 and a second line 271b electrically connected with the second electrode layer 213.

The first line 271a of the first signal cable 271 may be electrically connected with the first electrode layer 212 of the active vibration device 210 through the through region 255. For example, the first line 271a of the first signal cable 271 may be connected with the first electrode layer 212 of the active vibration device 210 and may extend to the outside along a region between the first cover member 235 and the second cover member 237.

The second line 271b of the first signal cable 271 may be electrically connected with the second electrode layer 213 of the active vibration device 210 through the through region 255. For example, the second line 271b of the first signal cable 271 may be connected with the second electrode layer 213 of the active vibration device 210 and may extend to the outside along a region between the first cover member 235 and the second cover member 237.

An apparatus according to various aspects of the present disclosure will be described below.

An apparatus according to various aspects of the present disclosure may include a vibration member, an active vibration device vibrating the vibration member, and a passive vibration device disposed at a periphery of the active vibration device to generate electrical energy, based on a deformation of the passive vibration device.

According to various aspects of the present disclosure, the active vibration device and the passive vibration device may be connected with a rear surface of the vibration member.

According to various aspects of the present disclosure, the passive vibration device may be deformed by a vibration of the vibration member.

According to various aspects of the present disclosure, the active vibration device and the passive vibration device may not overlap with each other on the vibration member.

According to various aspects of the present disclosure, the passive vibration device may include a plurality of passive vibration devices, and at least a portion of a periphery of the active vibration device may be surrounded by the plurality of passive vibration devices.

According to various aspects of the present disclosure, the passive vibration device may include at least one opening region, and the active vibration device may be disposed in the at least one opening region.

According to various aspects of the present disclosure, the apparatus may further include a signal cable connected with the active vibration device, and the at least one opening region may include a through region through which the signal cable passes.

According to various aspects of the present disclosure, the apparatus may further include a supporting plate covering at least a portion of each of the active vibration device and the passive vibration device.

According to various aspects of the present disclosure, the supporting plate may be connected with the active vibration device and the passive vibration device in common.

According to various aspects of the present disclosure, the supporting plate may be connected with the passive vibration device and may not connected with the active vibration device.

According to various aspects of the present disclosure, each of the active vibration device and the passive vibration device may include a first electrode layer at a first surface of each of the active vibration device and the passive vibration device, and a second electrode layer at a second surface different from the first surface of each of the active vibration device and the passive vibration device.

According to various aspects of the present disclosure, the first electrode layer and the second electrode layer of the active vibration device may be electrically disconnected with the first electrode layer and the second electrode layer of the passive vibration device.

According to various aspects of the present disclosure, the active vibration device and the passive vibration device may include a same material or different materials.

According to various aspects of the present disclosure, the active vibration device may include an active vibration part between the first electrode layer and the second electrode layer of the active vibration device. The passive vibration device may include a passive vibration part between the first electrode layer and the second electrode layer of the passive vibration device.

According to various aspects of the present disclosure, each of the active vibration part and the passive vibration part may include an inorganic material portion having a dielectric elastomer or a piezoelectric characteristic.

According to various aspects of the present disclosure, at least one of the active vibration part and the passive vibration part may include a dielectric elastomer.

According to various aspects of the present disclosure, at least one of the active vibration part and the passive vibration part may include a plurality of inorganic material portions having a piezoelectric characteristic, and an organic material portion between the plurality of inorganic material portions.

According to various aspects of the present disclosure, the first electrode layer of the passive vibration device may be closer to the vibration member than the second electrode layer of the passive vibration device. The second electrode layer may be configured to have stiffness different from stiffness of the first electrode layer of the passive vibration device, or may be configured to have stiffness greater than or equal to stiffness of the first electrode layer of the passive vibration device.

According to various aspects of the present disclosure, each of the active vibration device and the passive vibration device may include a first cover member connected with each of the first electrode layer of the active vibration device and the first electrode layer of the passive vibration device, and a second cover member connected with each of the second electrode layer of the active vibration device and the second electrode layer of the passive vibration device.

According to various aspects of the present disclosure, the active vibration device and the passive vibration device may include a first cover member connected with each of the first electrode layer of the active vibration device and the first electrode layer of the passive vibration device in common, and a second cover member connected with each of the second electrode layer of the active vibration device and the second electrode layer of the passive vibration device in common.

According to various aspects of the present disclosure, the apparatus may further include a signal cable connected with each of the first electrode layer and the second electrode layer of the active vibration device or the passive vibration device, and each of the first cover member and the second cover member may include at least one hole through which the signal cable passes.

According to various aspects of the present disclosure, the vibration member may include one or more of a display panel including a pixel configured to display an image, a screen panel on which an image is to be projected from a display apparatus, a lighting panel, a signage panel, a vehicular interior material, a vehicular glass window, a vehicular external material, a ceiling material of a building, an interior material of a building, a window of a building, an interior material of an aircraft, a window of an aircraft, metal, wood, rubber, plastic, glass, fiber, cloth, paper, leather, and mirror.

The apparatus according to an aspect of the present disclosure may be applied to or included in a sound apparatus provided in the apparatus. The apparatus according to an aspect of the present disclosure may be applied to mobile apparatuses, video phones, smart watches, watch phones, wearable apparatuses, foldable apparatuses, rollable apparatuses, bendable apparatuses, flexible apparatuses, curved apparatuses, portable multimedia players (PMPs), personal digital assistants (PDAs), electronic organizers, desktop personal computers (PCs), laptop PCs, netbook computers, workstations, navigation apparatus, automotive navigation apparatuses, automotive display apparatuses, televisions (TVs), wall paper display apparatuses, signage apparatuses, game machines, notebook computers, monitors, cameras, camcorders, home appliances, etc. Also, the sound apparatus according to the present disclosure may be applied to organic light emitting lighting apparatuses or inorganic light emitting lighting apparatuses. In a case where the sound apparatus is applied to a lighting device, the lighting device may act as lighting and a speaker. Also, in a case where the sound apparatus according to the present disclosure is applied to or included in a mobile apparatus, the sound apparatus may be one or more of a speaker, a receiver, and a haptic, but aspects of the present disclosure are not limited thereto.

It will be apparent to those skilled in the art that various modifications and variations may be made in the present disclosure without departing from the scope of the disclosure. Thus, it is intended that the present disclosure covers the modifications and variations of this disclosure provided that within the scope of the claims and their equivalents.

What is claimed is:

1. An apparatus, comprising:
a vibration member;
an active vibration device configured to vibrate the vibration member; and
a passive vibration device disposed at a periphery of the active vibration device and configured to generate electrical energy based on a deformation of the passive vibration device.

2. The apparatus of claim 1, wherein the active vibration device and the passive vibration device are connected with a rear surface of the vibration member.

3. The apparatus of claim 1, wherein the passive vibration device is deformed by a vibration of the vibration member.

4. The apparatus of claim 1, wherein the active vibration device and the passive vibration device do not overlap with each other on the vibration member.

5. The apparatus of claim 1, wherein the passive vibration device comprises a plurality of passive vibration devices, and
wherein at least a portion of a periphery of the active vibration device is surrounded by the plurality of passive vibration devices.

6. The apparatus of claim 1, wherein the passive vibration device comprises at least one opening region, and
wherein the active vibration device is disposed in the at least one opening region.

7. The apparatus of claim 6, further comprising a signal cable connected with the active vibration device,
wherein the at least one opening region comprises a through region through which the signal cable passes.

8. The apparatus of claim 1, further comprising a supporting plate covering at least a portion of each of the active vibration device and the passive vibration device.

9. The apparatus of claim 8, wherein the supporting plate is connected with the active vibration device and the passive vibration device in common.

10. The apparatus of claim 8, wherein the supporting plate is connected with the passive vibration device and is not connected with the active vibration device.

11. The apparatus of claim 1, wherein each of the active vibration device and the passive vibration device comprises:
a first electrode layer disposed at a first surface of each of the active vibration device and the passive vibration device; and
a second electrode layer disposed at a second surface different from the first surface of each of the active vibration device and the passive vibration device.

12. The apparatus of claim 11, wherein the first electrode layer and the second electrode layer of the active vibration device are electrically disconnected with the first electrode layer and the second electrode layer of the passive vibration device.

13. The apparatus of claim 11, wherein the active vibration device and the passive vibration device comprise a same material or different materials.

14. The apparatus of claim 11, wherein the active vibration device comprises an active vibration part between the first electrode layer and the second electrode layer of the active vibration device, and
wherein the passive vibration device comprises a passive vibration part between the first electrode layer and the second electrode layer of the passive vibration device.

15. The apparatus of claim 14, wherein each of the active vibration part and the passive vibration part comprises an inorganic material portion having a dielectric elastomer or a piezoelectric characteristic.

16. The apparatus of claim 14, wherein at least one of the active vibration part and the passive vibration part comprises a dielectric elastomer.

17. The apparatus of claim 14, wherein at least one of the active vibration part and the passive vibration part comprises:
a plurality of inorganic material portions having a piezoelectric characteristic; and
an organic material portion disposed between the plurality of inorganic material portions.

18. The apparatus of claim 11, wherein the first electrode layer of the passive vibration device is closer to the vibration member than the second electrode layer of the passive vibration device, and
wherein the second electrode layer of the passive vibration device is configured to have stiffness different from stiffness of the first electrode layer of the passive vibration device, or is configured to have stiffness greater than or equal to stiffness of the first electrode layer of the passive vibration device.

19. The apparatus of claim 11, wherein each of the active vibration device and the passive vibration device comprises:
a first cover member connected with each of the first electrode layer of the active vibration device and the first electrode layer of the passive vibration device; and
a second cover member connected with each of the second electrode layer of the active vibration device and the second electrode layer of the passive vibration device.

20. The apparatus of claim 11, wherein the active vibration device and the passive vibration device comprises:
a first cover member connected with each of the first electrode layer of the active vibration device and the first electrode layer of the passive vibration device in common; and
a second cover member connected with each of the second electrode layer of the active vibration device and the second electrode layer of the passive vibration device in common.

21. The apparatus of claim 20, further comprising a signal cable connected with each of the first electrode layer and the second electrode layer of the active vibration device or the passive vibration device,
wherein each of the first cover member and the second cover member comprises at least one hole through which the signal cable passes.

22. The apparatus of claim 1, wherein the vibration member comprises
one or more of a display panel including a pixel configured to display an image,
a screen panel on which an image is to be projected from a display apparatus, a lighting panel, a signage panel, a vehicular interior material, a vehicular glass window, a vehicular external material, a ceiling material of a building, an interior material of a building, a window of a building, an interior material of an aircraft, a window of an aircraft, metal, wood, rubber, plastic, glass, fiber, cloth, paper, leather, and mirror.
